(19) United States
(12) Patent Application Publication
(10) Pub. No.: US 2022/0356297 A1
(43) Pub. Date: Nov. 10, 2022

(54) RESIST UNDERLAYER FILM-FORMING COMPOSITION CONTAINING HETEROCYCLIC COMPOUND

(71) Applicant: NISSAN CHEMICAL CORPORATION, Tokyo (JP)

(72) Inventors: Satoshi KAMIBAYASHI, Toyama-shi (JP); Yuki ENDO, Toyama-shi (JP)

(73) Assignee: NISSAN CHEMICAL CORPORATION, Tokyo (JP)

(21) Appl. No.: 17/763,253

(22) PCT Filed: Oct. 9, 2020
(86) PCT No.: PCT/JP2020/038222

§ 371 Date: Mar. 24, 2022

(30) Foreign Application Priority Data
Oct. 10, 2019 (JP) 2019-186784

(51) Int. Cl. C08G 59/26; G03F 7/20; G03F 7/11; H01L 21/308

(52) U.S. Cl. CPC C08G 59/26; G03F 7/20; G03F 7/11; H01L 21/3081

(57) ABSTRACT

A resist underlayer film having an especially high dry etching rate; a composition for forming the resist underlayer film; a method for forming a resist pattern; and a method for producing a semiconductor device. The composition for forming the resist underlayer film has a solvent and a product of reaction between an epoxidized compound and a heterocyclic compound containing at least one moiety having reactivity with an epoxy group. It is preferable that the heteroring contained in the heterocyclic compound be selected from among furan, pyrrole, pyran, imidazole, pyrazole, oxazole, thiophene, thiazole, thiadiazole, imidazolidine, thiazolidine, imidazoline, dioxane, morpholine, diazine, thiazine, triazole, tetrazole, dioxolane, pyridazine, pyrimidine, pyrazine, piperidine, piperazine, indole, purine, quinoline, isoquinoline, quinuclidine, chromene, thianthrene, phenothiazine, phenoxazine, xanthene, acridine, phenazine, and carbazole.

### TECHNICAL FIELD

The present invention relates to a resist underlayer film-forming composition having a particularly high dry etching rate, to a resist underlayer film and a method for production thereof using the resist underlayer film-forming composition, to a method for forming a resist pattern, and to a method for manufacturing a semiconductor device.

### BACKGROUND ART

Photoexposure of a resist film is sometimes adversely affected by reflected waves. A resist underlayer film called an antireflection film is formed in order to prevent this.

A resist underlayer film is formed by applying a solution of a resist underlayer film-forming composition and curing the composition. To realize easy film formation, it is necessary that the composition be easily cured by treatment such as heating and that the compound (the polymer) contained in the composition have high solubility with respect to a predetermined type of a solvent.

A resist pattern formed on a resist underlayer film desirably has a rectangular cross section (a straight skirt shape that is not undercut or is not broad) in the direction perpendicular to a substrate. If, for example, a resist pattern has an undercut shape or a broad skirt shape, problems are encountered such as that the resist pattern is collapsed and that a workpiece (such as a substrate or an insulating film) cannot be processed into a desired shape or size by a lithographic process.

Further, a resist underlayer film is required to have a higher dry etching rate than a resist film disposed thereon, that is, to offer high selectivity in dry etching rate.

Patent Literature 1 discloses a resist underlayer film-forming composition that includes a polymer having a disulfide bond in the backbone. Patent Literature 2 discloses an epoxy compound having a glycidyl ester group. Patent Literature 3 discloses a composition for forming anti-reflective coating characterized in that the composition includes a triazine trione compound, oligomer compound or polymer compound having a hydroxyalkyl structure as a substituent on a nitrogen atom.

### CITATION LIST

### Patent Literature

Patent Literature 1: JP 2009-096340 A
Patent Literature 2: JP H8-81461 A
Patent Literature 3: JP 2004-034148 A

### SUMMARY OF INVENTION

### Technical Problem

In the manufacturing of semiconductor elements, there is still a demand for resist underlayer films having a high dry etching rate. A known approach to increasing the dry etching rate of a resist underlayer film is to add a heteroatom-containing polymer to a composition.

After extensive studies, the present inventors have found that a higher etching rate than the conventional techniques can be achieved by designing a resist underlayer film-forming composition to include a reaction product of an epoxy group-containing compound, preferably a glycidyl ester group-containing compound, preferably a nitrogen-containing heterocyclic compound (such as isocyanuric acid) having a glycidyl ester group, and a heterocyclic compound containing one site reactive with an epoxy group.

To solve the problems discussed hereinabove, an object of the present invention is to provide a resist underlayer film-forming composition having a particularly high dry etching rate. Other objects of the present invention are to provide a resist underlayer film and a method for production thereof using the resist underlayer film-forming composition, to provide a method for forming a resist pattern, and to provide a method for manufacturing a semiconductor device.

### Solution to Problem

Aspects of the present invention include the following.

[1] A resist underlayer film-forming composition comprising a solvent and a reaction product formed between an epoxy group-containing compound and a heterocyclic compound having one site reactive with an epoxy group.

[2] The resist underlayer film-forming composition according to [1], wherein the heterocyclic compound includes a heterocyclic ring selected from furan, pyrrol, pyran, imidazole, pyrazole, oxazole, thiophene, thiazole, thiadiazole, imidazolidine, thiazolidine, imidazoline, dioxane, morpholine, diazine, thiazine, triazole, tetrazole, dioxolane, pyridazine, pyrimidine, pyrazine, piperidine, piperazine, indole, purine, quinoline, isoquinoline, quinuclidine, chromene, thianthrene, phenothiazine, phenoxazine, xanthene, acridine, phenazine and carbazole.

[3] The resist underlayer film-forming composition according to [1] or [2], wherein the site reactive with an epoxy group is selected from a hydroxy group, a thiol group, an amino group, an imide group and a carboxyl group.

[4] The resist underlayer film-forming composition according to any one of claims 1 to 3, wherein the epoxy group-containing compound is a compound represented by the following formula (1):

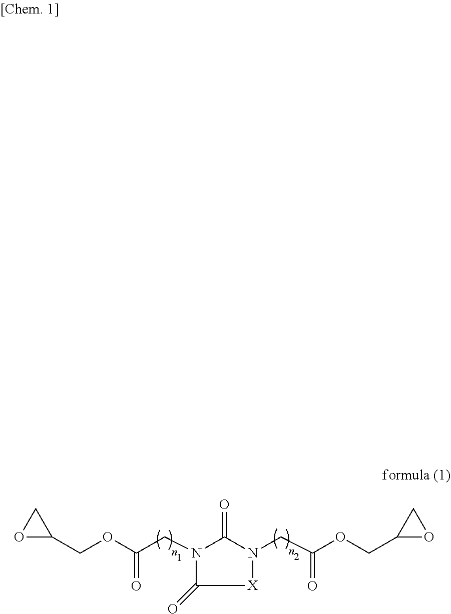

wherein X is a divalent organic group represented by formula (2), formula (3) or formula (4) below, and n₁ and n₂ are each independently an integer of 1 to 10,

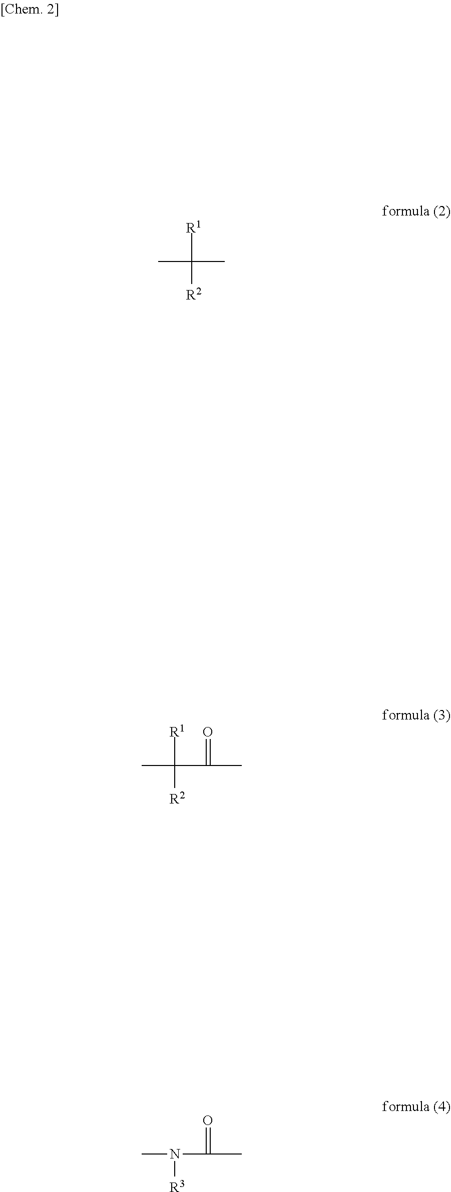

wherein

R¹ and R² each independently denote a hydrogen atom, a C₁-C₁₀ alkyl group optionally interrupted with an oxygen atom or a sulfur atom, a C₂-C₁₀ (alkenyl group optionally interrupted with an oxygen atom or a sulfur atom, a C₂-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group and C₁-C₆ alkylthio groups; and

R³ denotes a hydrogen atom, a C₁-C₁₀ alkyl group optionally interrupted with an oxygen atom or a sulfur atom, a C₃-C₁₀ alkenyl group optionally interrupted with an oxygen atom or a sulfur atom, a C₃-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group, C₁-C₆ alkylthio groups and organic groups represented by the following formula (5):

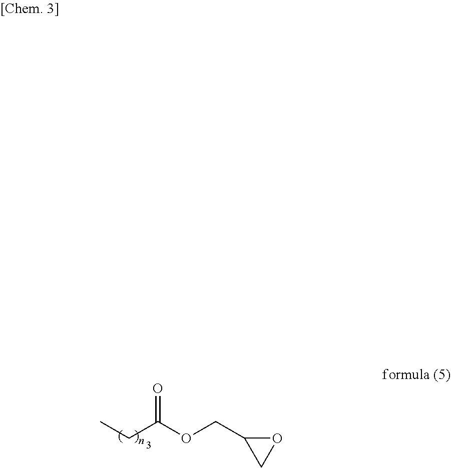

wherein n3 indicates an integer of 1 to 1).

[5] The resist underlayer film-forming composition according to any one of [1] to [4], further comprising at least one component selected from the group consisting of crosslinking agent, crosslinking catalyst and surfactant.

[6] A resist underlayer film comprising a calcined product of a coating film comprising the resist underlayer film-forming composition according to any one of [1] to [5].

[7] A method for producing a pattern-bearing substrate, comprising the steps of:

applying the resist underlayer film-forming composition according to any one of [1] to [5] onto a semiconductor substrate and baking the resist underlayer film-forming composition to form a resist underlayer film,

applying a resist onto the resist underlayer film and baking the resist to form a resist film,

exposing the semiconductor substrate coated with the resist underlayer film and the resist, and developing the exposed resist film to perform patterning.

[8] A method for manufacturing a semiconductor device, comprising the steps of:

forming, on a semiconductor substrate, a resist underlayer film from the resist underlayer film-forming composition according to any one of [1] to [5],

forming a resist film on the resist underlayer film,

applying a light or electron beam to the resist film followed by development to form a resist pattern,

etching the resist underlayer film through the resist pattern to form a patterned resist underlayer film, and

a step of processing the semiconductor substrate through the patterned resist underlayer film.

[9] A reaction product of a compound represented by formula (1) below and a heterocyclic compound having one site reactive with an epoxy group

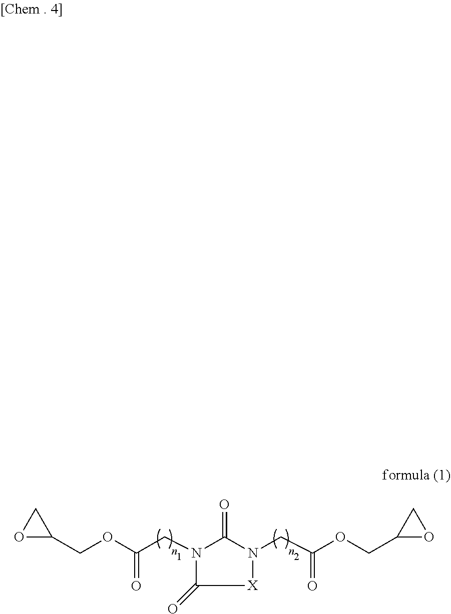

wherein X is a divalent organic group represented by formula (2), formula (3) or formula (4) below, and n₁ and n₂ are each independently an integer of 1 to 10,

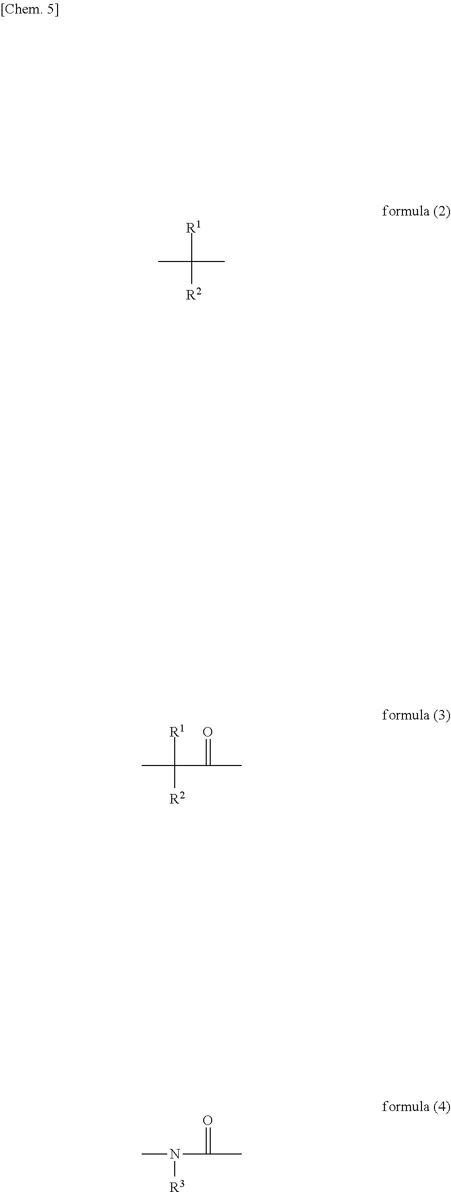

wherein

R¹ and R² each independently denote a hydrogen atom, a C₁-C₁₀ alkyl group optionally interrupted with an oxygen atom or a sulfur atom, a C₂-C₁₀ alkenyl group optionally interrupted with an oxygen atom or a sulfur atom, a C₂-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group and C₁-C₁₀ alkylthio groups; and

R³ denotes a hydrogen atom, a C₁-C₁₀ alkyl group optionally interrupted with an oxygen atom or a sulfur atom, a C₃-C₁₀ alkenyl group optionally interrupted with an oxygen atom or a sulfur atom, a Ci-Cu alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group, C₁-C₆ alkylthio groups and organic groups represented by the following formula (5):

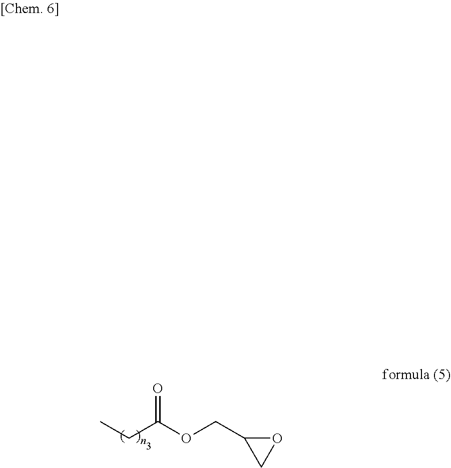

wherein n3 indicates an integer of 1 to 10.

### Advantageous Effects of Invention

The resist underlayer film-forming composition of the present invention has a high dry etching rate, can solve various problems stemming from thinning of resist films, and allows for finer processing of semiconductor substrates.

### DESCRIPTION OF EMBODIMENTS

<Resist underlayer film-forming composition, and reaction product of an epoxy group-containing compound and a heterocyclic compound having one site reactive with epoxy group>

A resist underlayer film-forming composition of the present application includes a solvent and a reaction product of an epoxy group-containing compound and a heterocyclic compound having one site reactive with an epoxy group.

The epoxy group-containing compound is not limited as long as the objects described hereinabove are achieved. A glycidyl ester group-containing compound is preferable, and a nitrogen-containing heterocyclic compound (such as isocyanuric acid) having glycidyl ester groups is preferable.

For example, the epoxy group-containing compound may be a compound containing a C₆-C₄₀ aromatic ring structure, a compound containing triazinone, a compound containing triazinedione, or a compound containing triazinetrione, and is preferably a compound containing triazinetrione.

The epoxy group-containing compound is preferably a compound represented by the following formula (1):

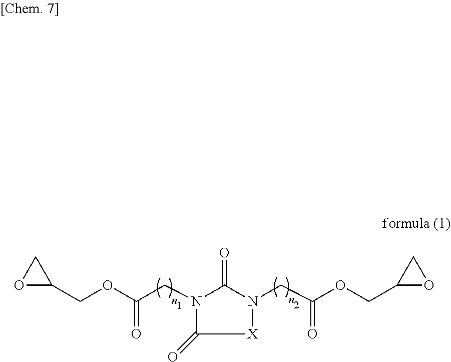

wherein X is a divalent organic group represented by formula (2), formula (3) or formula (4) below, and n₁ and n₂ are each independently an integer of 1 to 10,

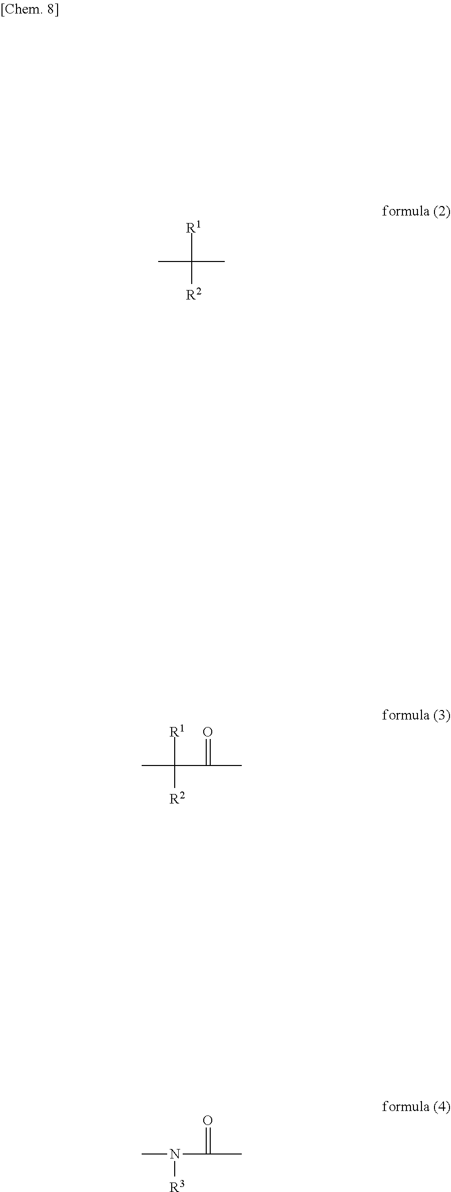

wherein

R¹ and R² each independently denote a hydrogen atom, a C₁-C₁₀ alkyl group optionally interrupted with an oxygen atom or a sulfur atom, a C₂-C₁₀ alkenyl group optionally interrupted with an oxygen atom or a sulfur atom, a C₂-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group and C₁-C₆ alkylthio groups; and

R³ denotes a hydrogen atom, a C₁-C₁₀ alkyl group optionally interrupted with an oxygen atom or a sulfur atom, a C₃-C₁₀ alkenyl group optionally interrupted with an oxygen atom or a sulfur atom, a C₃-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group, C₁-C₆ alkylthio groups and organic groups represented by the following formula (5):

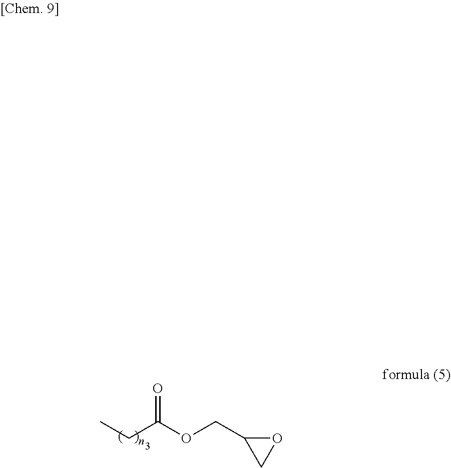

wherein n3 indicates an integer of 1 to 10.

Examples of the C₁-C₁₀ alkyl groups include methyl group, ethyl group, n-propyl group, i-propyl group, cyclopropyl group, n-butyl group, i-butyl group, s-butyl group, t-butyl group, cyclobutyl group, 1-methyl-1-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-1-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group and 2-ethyl-3-methyl-cyclopropyl group.

Examples of the C₂-C₁₀ alkenyl groups include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimthyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group 2-cyclohexenyl group and 3-cyclohexenyl group.

Examples of the C₂-C₁₀ alkynyl groups include ethynyl group, 1-propynyl group, 2-propynyl group, 1-butynyl group, 2-butynyl group, 3-butynyl group, 4-methyl-1-pentynyl group and 3-methyl-1-pentynyl group.

The phrase “optionally interrupted with an oxygen atom or a sulfur atom” means that a carbon atom in, for example, any of the alkyl, alkenyl and alkynyl groups described above is replaced by an oxygen atom or a sulfur atom. When, for example, a carbon atom in the alkyl, alkenyl or alkynyl group is replaced by an oxygen atom, the group will contain an ether bond. When, for example, a carbon atom in the alkyl, alkenyl or alkynyl group is replaced by a sulfur atom, the group will contain a thioether bond.

Examples of the C₁-C₆ alkyl groups include those alkyl groups having 1 to 6 carbon atoms out of the C₁-C₁₀ alkyl groups described hereinabove.

Examples of the halogen atoms include fluorine, chlorine, bromine and iodine.

Examples of the C₁-C₁₀ alkoxy groups include methoxy group, ethoxy group, n-propoxy group, i-propoxy group, n-butoxy group, i-butoxy group, s-butoxy group, t-butoxy group, n-pentoxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group and 1-ethyl-2-methyl-n-propoxy group.

Examples of the C₁-C₆ alkylthio groups include ethylthio group, butylthio group and hexylthio group.

In formula (1), X is preferably represented by formula (4).

In formula (1), it is preferable that X be represented by formula (4), n1 and n2 be 1, and R³ be a C₁-C₅ alkyl group optionally interrupted with an oxygen atom. Specific examples of the C₁-C₅ alkyl groups in this case include those alkyl groups having 1 to 5 carbon atoms out of the Ct-Cm alkyl groups described hereinabove.

In formula (1), it is preferable that X be represented by formula (4), n1 and n2 be 1, R³ be a methyl group, a methoxymethyl group or represented by formula (5), and n3 be 1. That is, the compound is preferably represented by formula (A-1), formula (A-7) or formula (A-19) below.

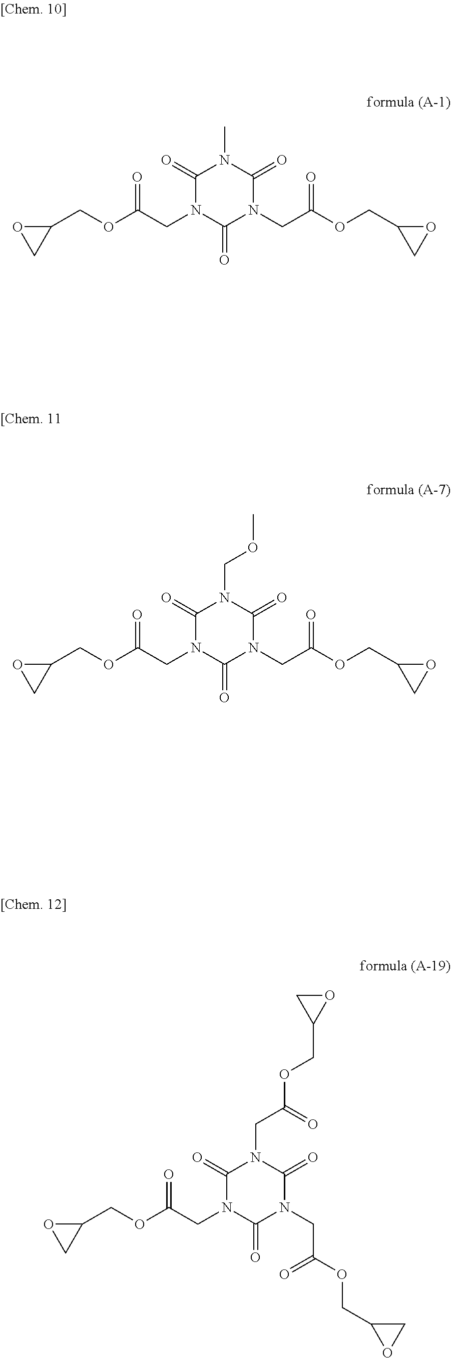 [SMILES: Cn1c(=O)n(CC(=O)OCC2CO2)c(=O)n(CC(=O)OCC2CO2)c1=O ; COCn1c(=O)n(CC(=O)OCC2CO2)c(=O)n(CC(=O)OCC2CO2)c1=O ; O=C(Cn1c(=O)n(CC(=O)OCC2CO2)c(=O)n(CC(=O)OCC2CO2)c1=O)OCC1CO1]

Examples of the compounds represented by formula (1) of the present application include, but are not limited to, those of the following formulas (A-1) to (A-21).

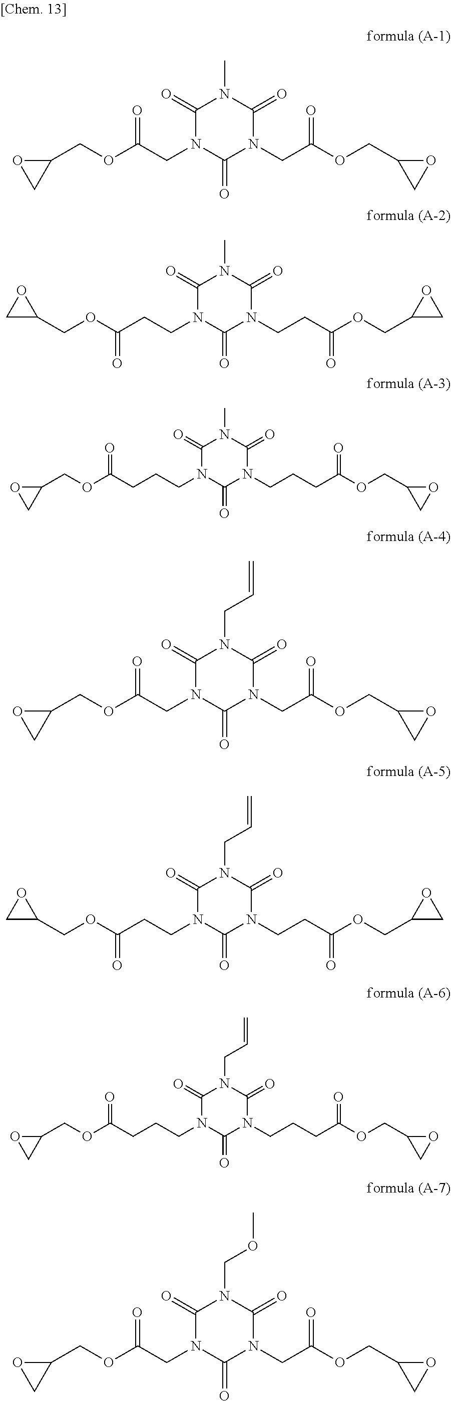

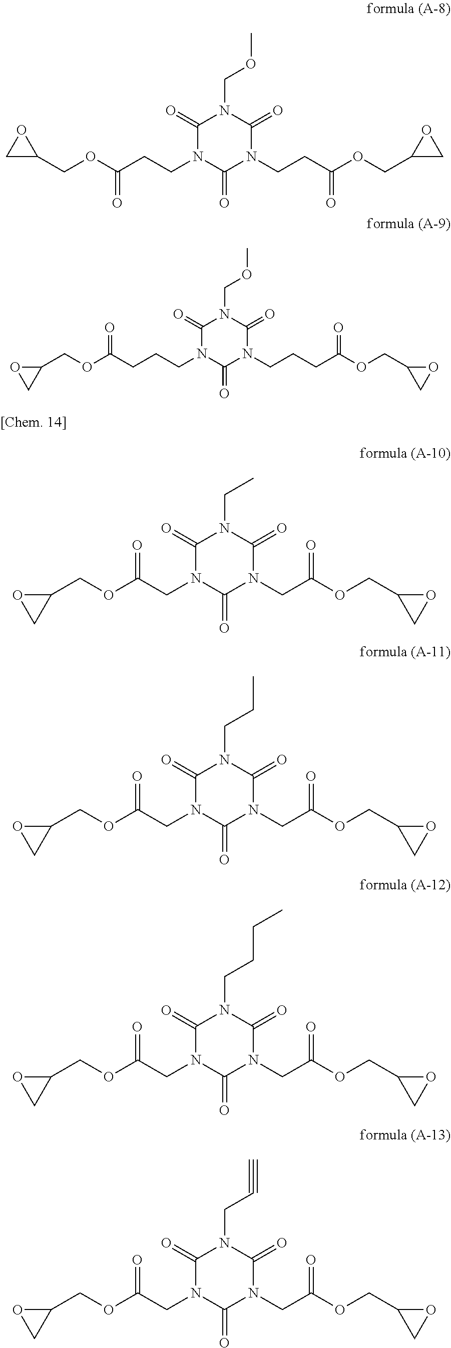 [SMILES: COCn1c(=O)n(CCC(=O)OCC2CO2)c(=O)n(CCC(=O)OCC2CO2)c1=O ; COCn1c(=O)n(CCCC(=O)OCC2CO2)c(=O)n(CCCC(=O)OCC2CO2)c1=O ; CCn1c(=O)n(CC(=O)OCC2CO2)c(=O)n(CC(=O)OCC2CO2)c1=O ; CCCn1c(=O)n(CC(=O)OCC2CO2)c(=O)n(CC(=O)OCC2CO2)c1=O ; CCCCn1c(=O)n(CC(=O)OCC2CO2)c(=O)n(CC(=O)OCC2CO2)c1=O ; C#CCn1c(=O)n(CC(=O)OCC2CO2)c(=O)n(CC(=O)OCC2CO2)c1=O]

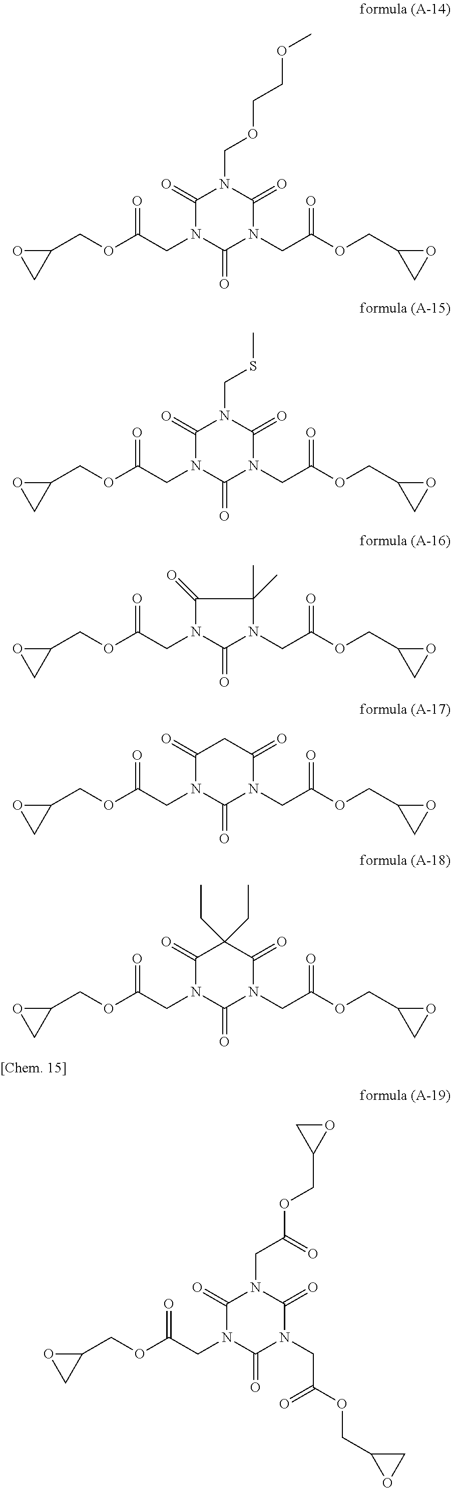 [SMILES: COCCOCn1c(=O)n(CC(=O)OCC2CO2)c(=O)n(CC(=O)OCC2CO2)c1=O ; CSCn1c(=O)n(CC(=O)OCC2CO2)c(=O)n(CC(=O)OCC2CO2)c1=O ; CC1(C)C(=O)N(CC(=O)OCC2CO2)C(=O)N1CC(=O)OCC1CO1 ; O=C(CN1C(=O)CC(=O)N(CC(=O)OCC2CO2)C1=O)OCC1CO1 ; CCC1(CC)C(=O)N(CC(=O)OCC2CO2)C(=O)N(CC(=O)OCC2CO2)C1=O ; O=C(Cn1c(=O)n(CC(=O)OCC2CO2)c(=O)n(CC(=O)OCC2CO2)c1=O)OCC1CO1]

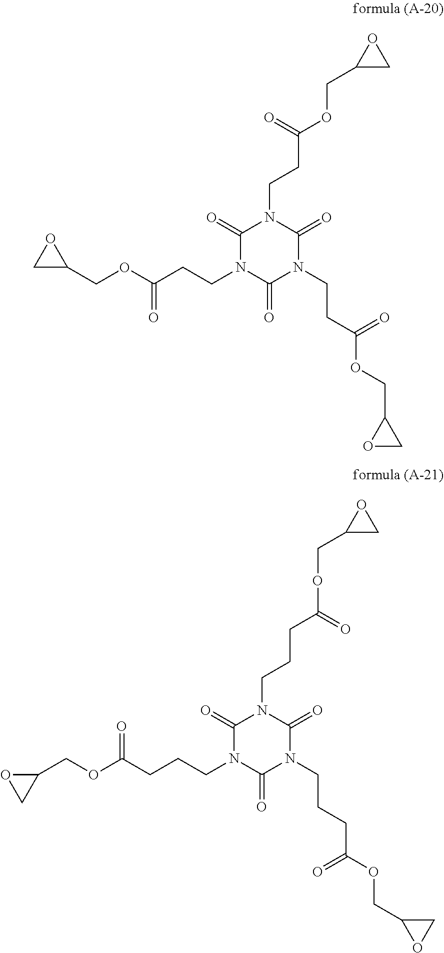 [SMILES: O=C(CCn1c(=O)n(CCC(=O)OCC2CO2)c(=O)n(CCC(=O)OCC2CO2)c1=O)OCC1CO1 ; O=C(CCCn1c(=O)n(CCCC(=O)OCC2CO2)c(=O)n(CCCC(=O)OCC2CO2)c1=O)OCC1CO1]

The epoxy group-containing compound may be selected from compounds (a) to (s) illustrated below. In formula (o), R⁰ denotes a C₁-C₁₀ alkylene group.

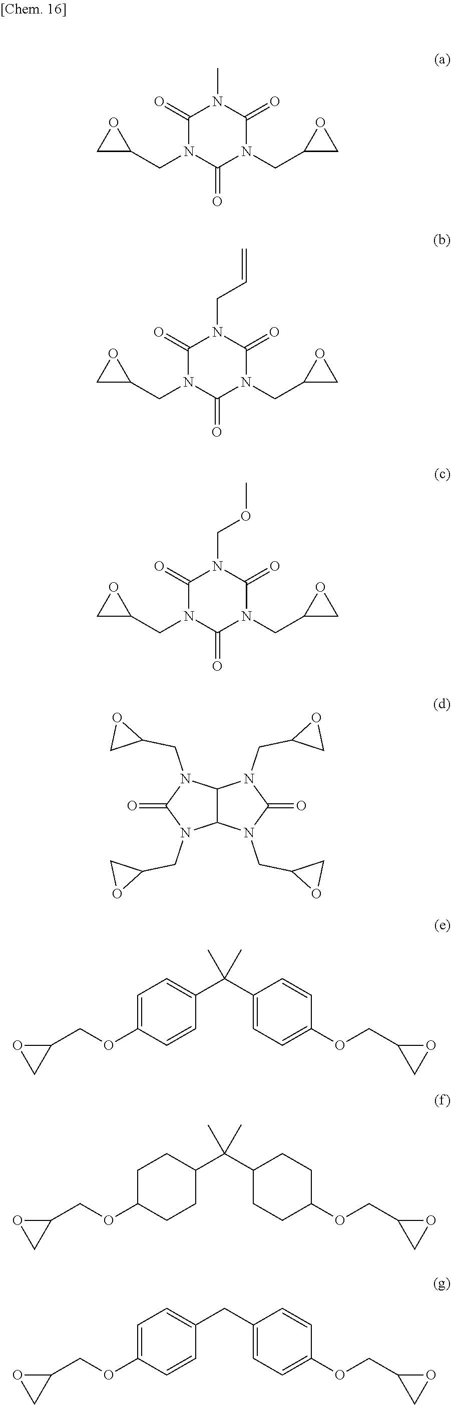

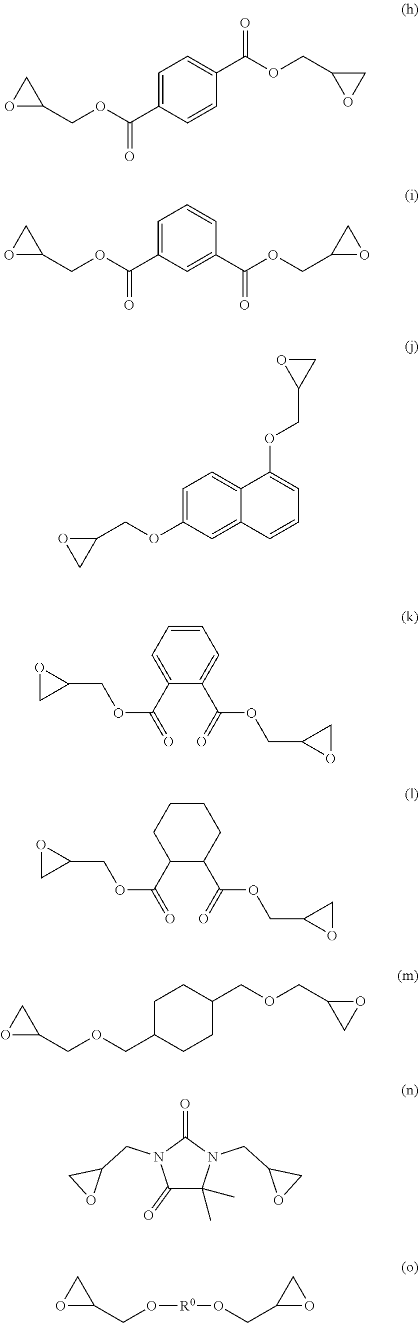

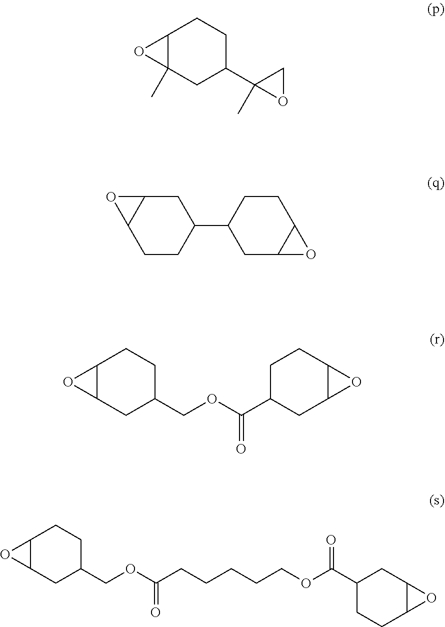 [SMILES: CC1(C2CCC3OC3(C)C2)CO1 ; C1CC2OC2CC1C1CCC2OC2C1 ; O=C(OCC1CCC2OC2C1)C1CCC2OC2C1 ; O=C(CCCCCOC(=O)C1CCC2OC2C1)OCC1CCC2OC2C1]

The epoxy group-containing compound may be a compound containing three or more epoxy groups as is illustrated below. Specific examples include glycidyl either compounds, glycidyl ester compounds, glycidyl amine compounds, and glycidyl group-containing isocyanurates. Examples of the epoxy group-containing compounds for use in the present invention include those of the following formulas (A0-1) to (A0-13).

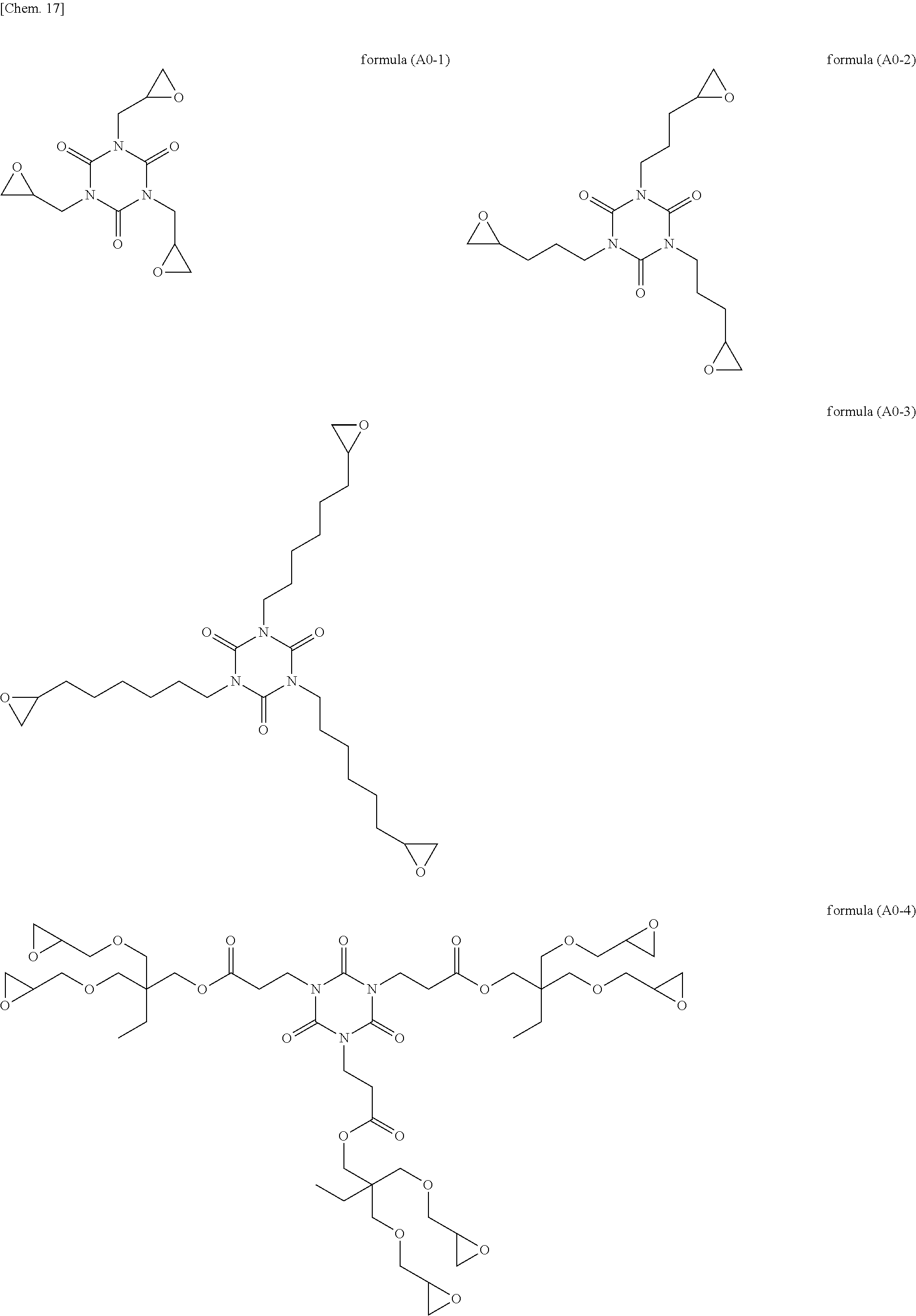 [SMILES: O=c1n(CC2CO2)c(=O)n(CC2CO2)c(=O)n1CC1CO1 ; O=c1n(CCCC2CO2)c(=O)n(CCCC2CO2)c(=O)n1CCCC1CO1 ; O=c1n(CCCCCCC2CO2)c(=O)n(CCCCCCC2CO2)c(=O)n1CCCCCCC1CO1 ; CCC(COCC1CO1)(COCC1CO1)COC(=O)CCn1c(=O)n(CCC(=O)OCC(CC)(COCC2CO2)COCC2CO2)c(=O)n(CCC(=O)OCC(CC)(COCC2CO2)COCC2CO2)c1=O]

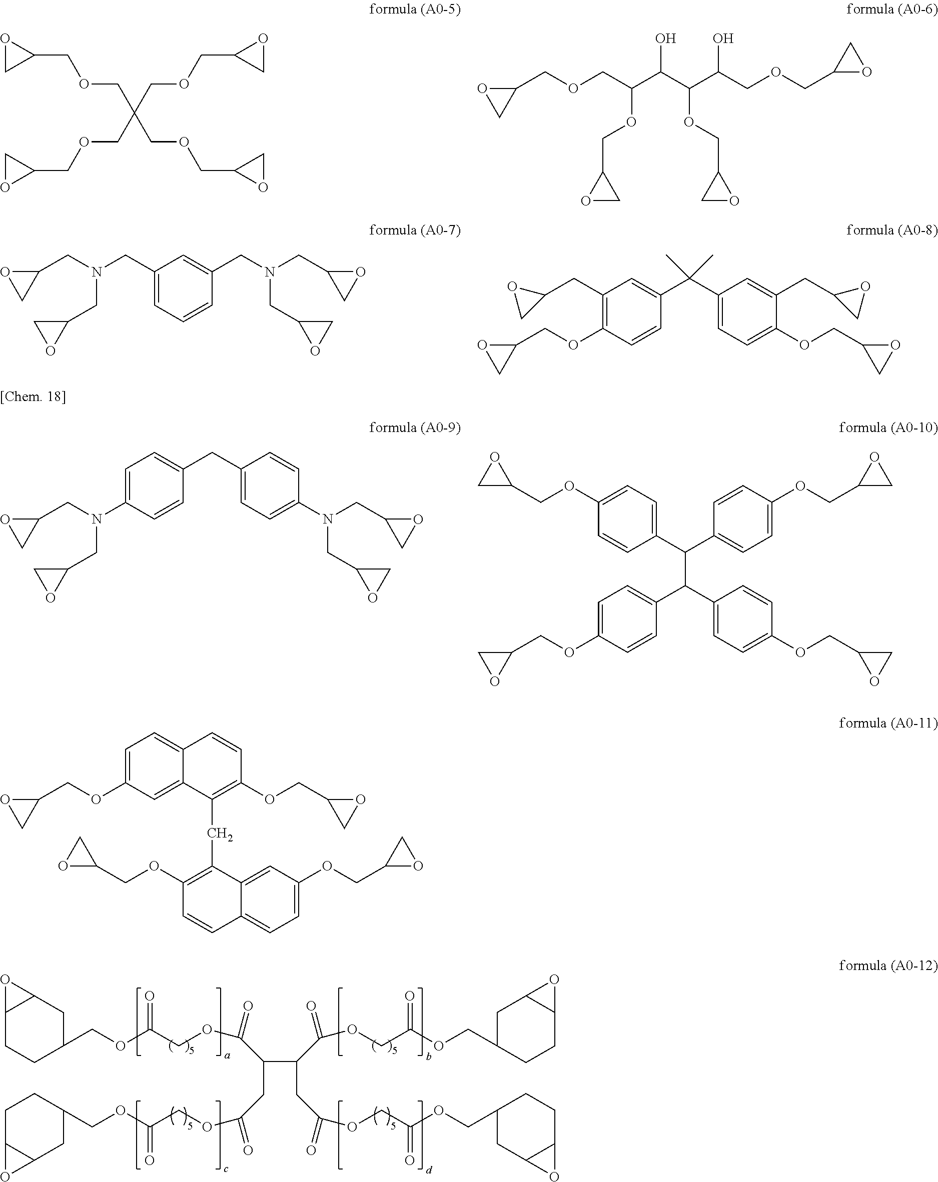

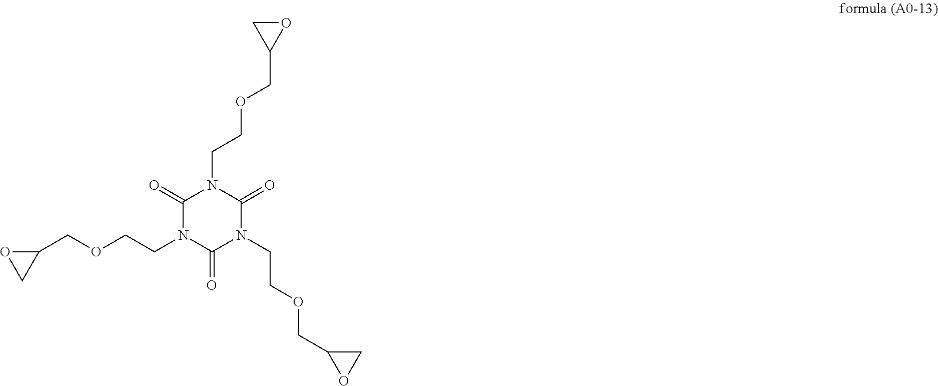 [SMILES: O=c1n(CCOCC2CO2)c(=O)n(CCOCC2CO2)c(=O)n1CCOCC1CO1]

Formula (A0-1) is available from Nissan Chemical Corporation under the trade names TEPIC-G, TEPIC-S, TEPIC-SS, TEPIC-HP and TEPIC-L (all 1,3,5-tris(2,3-epoxypropyl)isocyanurate).

Formula (A0-2) is available from Nissan Chemical Corporation under the trade name TEPIC-VL.

Formula (A0-3) is available from Nissan Chemical Corporation under the trade name TEPIC-FL.

Formula (A0-4) is available from Nissan Chemical Corporation under the trade name TEPIC-UC.

Formula (A0-5) is available from Nissan ChemteX Corporation under the name Denacol EX-411.

Formula (A0-6) is available from Nagase ChemteX Corporation under the trade name Denacol EX-521.

Formula (A0-7) is available from MITSUBISHI GAS CHEMICAL COMPANY, INC. under the trade name TETRAD-X.

Formula (A0-8) is available firm SHOWA DENKO K. K. under the trade name BATG.

Formula (A0-9) is available from Nippon Steel & Sumikin Chemical Co., Ltd. under the trade name YH-434L.

Formula (A0-10) is available from ASAHI YUKIZAI CORPORATION under the trade name TEP-G.

Formula (A0-11) is available from DIC CORPORATION under the trade name EPICLON HP-4700.

Formula (A0-12) is available from Daicel Corporation under the trade name EPOLEAD GT401. Incidentally, a, b, c and d are each 0 or 1, and a+b++c+d=1.

The following epoxy compounds may also be used.

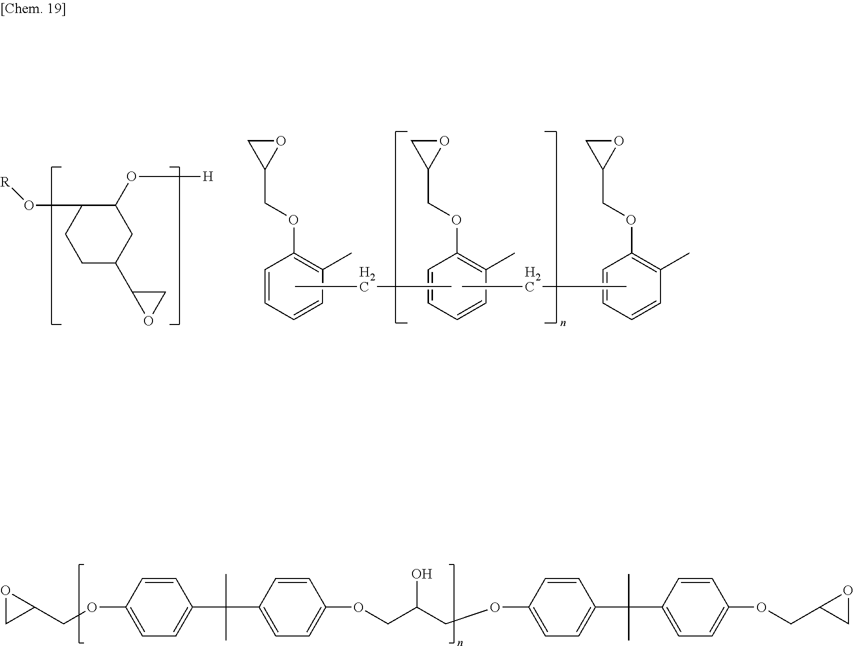

The epoxy group-containing compound described above may be reacted with a heterocyclic compound having one site reactive with an epoxy group by a method that is known per se.

The heterocyclic compound is a compound that contains any of the heterocyclic rings described below.

The heterocyclic ring is preferably selected from furan, pyrrol, pyran, inidazole, pyrazole, oxazole, thiophene, thiazole, thiadiazole, imidazolidine, thiazolidine, imidazoline, dioxane, morpholine, diazine, thiazine, triazole, tetrazole, dioxolane, pyridazine, pyrimidine, pyrazine, piperidine, piperazine, indole, purine, quinoline, isoquinoline, quinuclidine, chromene, thianthrene, phenothiazine, phenoxazine, xanthene, acridine, phenazine and carbazole.

The heterocyclic rings enumerated above may be substituted with a substituent such as, for example, a C₁-C₅ alkyl group and methylthio group on any one of the elements.

Of those enumerated above, a heterocyclic ring selected from thiophene, tetrazole, thiazole and thiadiazole is preferable for the reason that the dry etching rate of a resist underlayer film is particularly increased.

The site reactive with an epoxy group is preferably selected from a hydroxy group, a thiol group, an amino group, an imide group and a carboxyl group.

Of those enumerated above, a carboxyl group and a thiol group are preferable for the reason that the dry etching rate of a resist underlayer film is particularly increased.

Specific examples of the heterocyclic compound having one site reactive with an epoxy group include the compounds illustrated below.

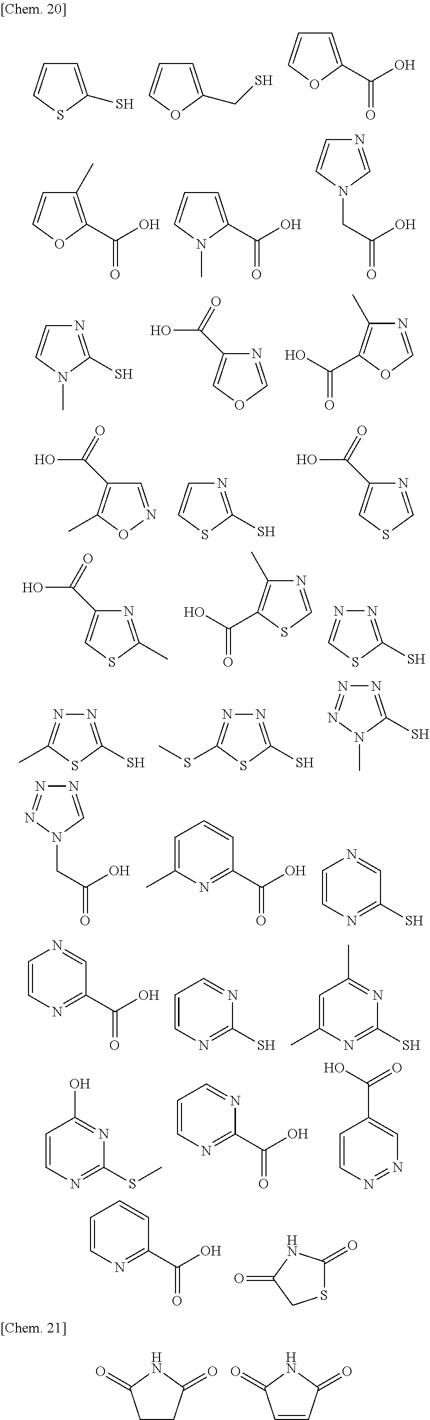

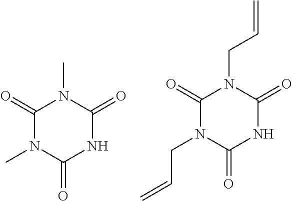

When the epoxy group in the compound represented by formula (1) is allowed to react with the heterocyclic compound having one site reactive with an epoxy group, the ratio of the numbers of moles (the former:the latter) ranges, for example, (0.1 to 1):1, and preferably (0.5 to 1):1.

The (remaining) epoxy groups in excess of the reaction equivalent amount may react with compounds other than the heterocyclic compound having one site reactive with an epoxy group (for example, aromatics and/or aliphatics having a site reactive with an epoxy group (such as aromatic carboxylic acids, aromatic thiols, aliphatic carboxylic acids, aromatic thiols, and heterocyclic compounds having two or more sites reactive with an epoxy group)).

Examples of such compounds having a site reactive with an epoxy group include, but are not limited to, the following formulas (B-1) to (B-62):

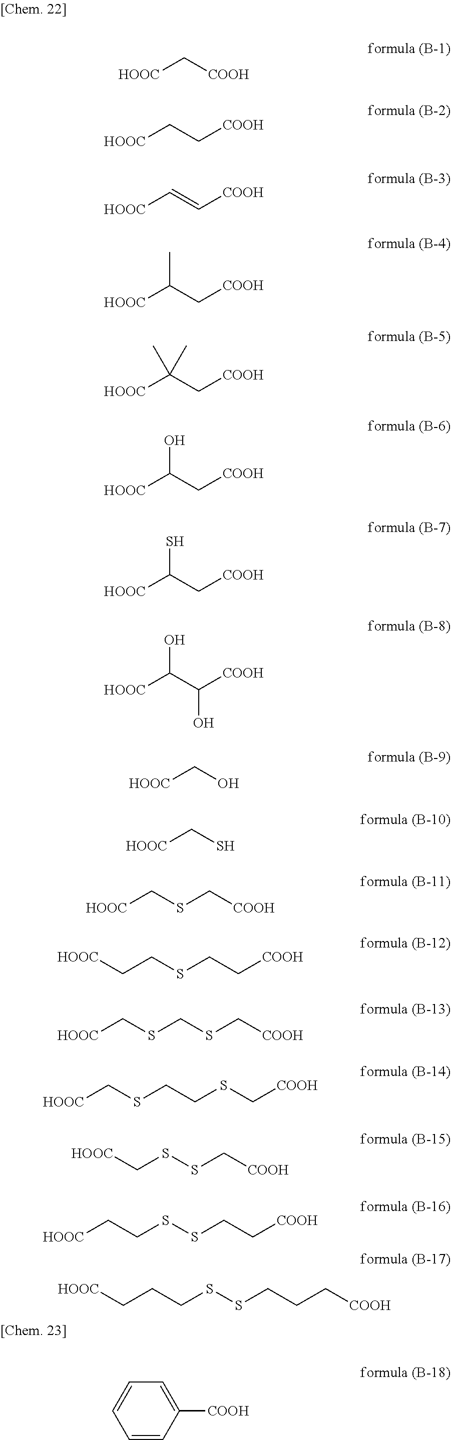

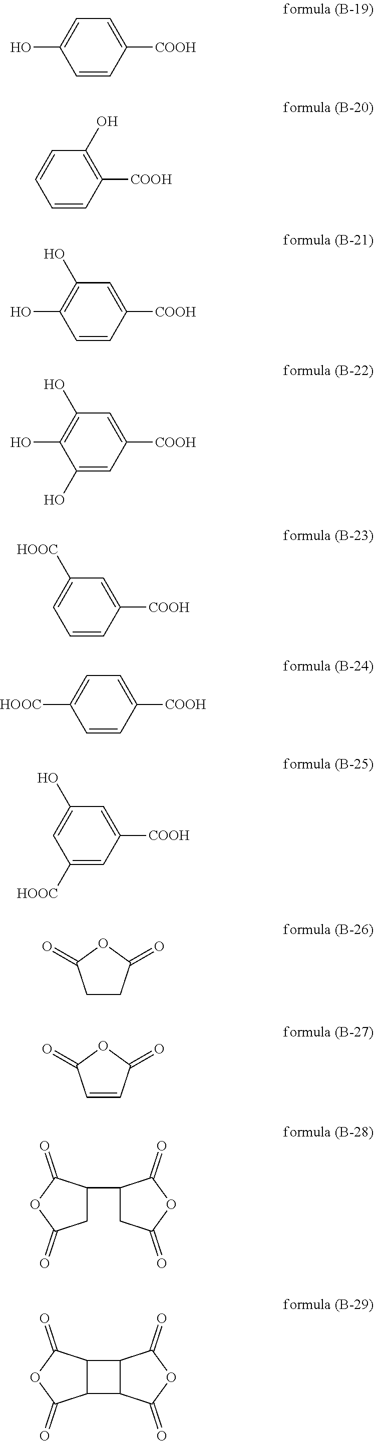

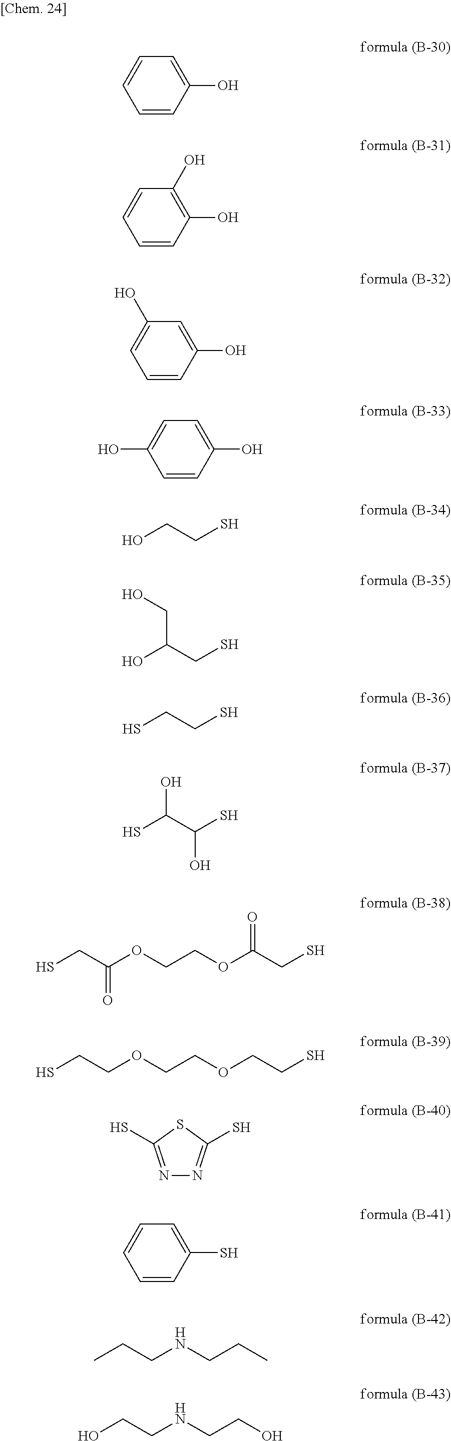

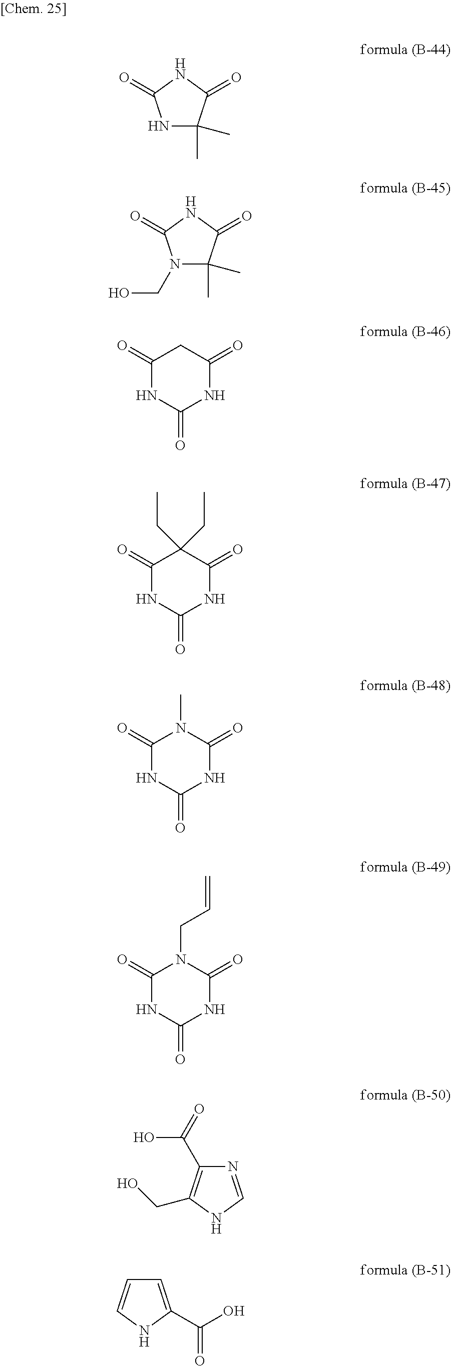

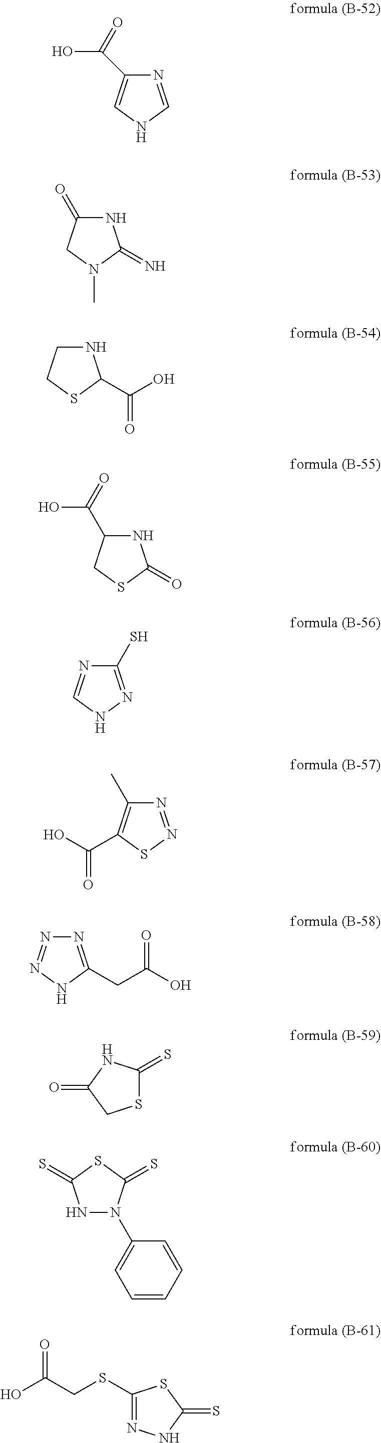

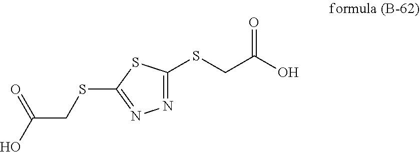 [SMILES: O=C(O)CSc1nnc(SCC(=O)O)s1]

The weight average molecular weight (Mw) of the reaction product in the present application is, for example, within the range of 300 to 4,000, or 400 to 3,000, or 500 to 2,000.

[Solvent]

The resist underlayer film-forming composition of the present invention may be produced by dissolving the component(s) described above into an organic solvent, and is used as a uniform solution.

The solvent used in the resist underlayer film-forming composition according to the present invention is not particularly limited as long as the solvent can dissolve the compounds described above or the reaction product thereof. In particular, it is recommended to use a combination of solvents commonly used in the lithographic process in consideration of the application performance of the resist underlayer film-forming composition of the present invention used as a uniform solution.

Examples of the organic solvents include ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide and N,N-dimethylacetamide. The solvents may be used each alone or in combination of two or more.

Of the solvents mentioned above, propylene glycol monomethyl ether, propylene glycol monomethyl ether acetate, ethyl lactate, butyl lactate and cyclohexanone are preferable. Propylene glycol monomethyl ether and propylene glycol monomethyl ether acetate are particularly preferable.

[Crosslinking Catalyst]

The resist underlayer film-forming composition of the present invention may contain a crosslinking catalyst as an optional component to promote the crosslinking reaction. Examples of the crosslinking catalysts include acidic compounds, basic compounds and compounds that generate an acid or a base when heated. Examples of the acidic compounds include sulfonic acid compounds and carboxylic acid compounds.

Examples of the compounds that generate an acid when heated include thermal acid generators.

Examples of the sulfonic acid compounds and the carboxylic acid compounds include phenolsulfonic acid, p-toluenesulfonic acid, trifluoromethanesulfonic acid, pyridinium trifluoromethanesulfonate, pyridinium-p-toluenesulfonate (pyridinium-p-phenolsulfonate), salicylic acid, camphorsulfonic acid, 5-sulfosalicylic acid, 4-chlorobenzenesulfonic acid, 4-hydroxybenzenesulfonic acid, pyridinium-4-hydroxybenzenesulfonate, benzenedisulfonic acid, 1-naphthalenesulfonic acid, 4-nitrobenzenesulfonic acid, citric acid, benzoic acid and hydroxybenzoic acid.

Examples of the thermal acid generators include K-PURE [registered trademark] series CXC-1612, CXC-1614, TAG-2172, TAG-2179, TAG-2678 and TAG-2689 (all manufactured by King Industries), and SI-45, SI-60, SI-80, SI-100, SI-110 and SI-150 (all manufactured by SANSHIN CHEMICAL INDUSTRY CO., LTD.)

The crosslinking catalysts may be used each alone or in combination of two or more, Examples of the basic compounds include amine compounds and ammonium hydroxide compounds. Examples of the compounds that generate a base when heated include urea.

Examples of the amine compounds include tertiary amines such as triethanolamine, tributanolamine, trimethylamine, triethylamine, tri-n-propylamine, triisopropylamine, tri-n-butylamine, tri-tert-butylamine, tri-n-octylamine, triisopropanolamine, phenyldiethanolamine, stearyldiethanolamine and diazabicyclooctane, and aromatic amines such as pyridine and 4-dimethylaminopyridine. Examples of the amine compounds further include primary amines such as benzylamine and n-butylamine, and secondary amines such as diethylamine and di-n-butylamine. The amine compounds may be used each alone or in combination of two or more.

Examples of the ammonium hydroxide compounds include tetramethylammonium hydroxide, tetraethylammonium hydroxide, tetrapropylammonium hydroxide, tetrabutylammonium hydroxide, benzyltrimethylammonium hydroxide, benzyltriethylammonium hydroxide, cetyltrimethylammonium hydroxide, phenyltrimethylammonium hydroxide and phenyltrimethylammonium hydroxide.

Examples of the compounds that generate a base when heated further include compounds that have a thermally labile group such as an amide group, a urethane group or an aziridine group and generate an amine when heated. Examples of the compounds that generate a base when heated further include urea, benzyltrimethylammonium chloride, benzyltriethylammonium chloride, benzyldimethylphenylammonium chloride, benzyldodecyidimethylammonium chloride, benzyltributylammonium chloride and choline chloride.

When the resist underlayer film-forming composition includes the crosslinking catalyst, the content thereof is within the range of 0.0001 to 20% by mass, preferably 0.01 to 15% t by mass, and more preferably 0.1 to 10% by mass based on the total solid content in the resist underlayer film-forming composition.

Of those mentioned above, the acidic compounds and/or the compounds that generate an acid when heated (the crosslinking acid catalysts) are preferable.

[Crosslinking Agent]

The resist underlayer film-forming composition of the present invention may include a crosslinking agent component. Examples of the crosslinking agent include melamine compounds, substituted urea compounds, and polymers thereof. The crosslinking agents having at least two crosslinking substituents are preferable, with examples including methoxymethylated glycoluril (for example, tetramethoxymethylglycoluril), butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea and methoxymethylated thiourea. Further, condensates of these compounds may also be used.

Of those mentioned above, methoxymethylated glycoluril (for example, tetramethoxyniethylglcoluril) is preferable.

The crosslinking agent that is used may be a crosslinking agent having high heat resistance. The crosslinking agent having high heat resistance may be a compound which contains, in the molecule, a crosslinking substituent having an aromatic ring (for example, a benzene ring or a naphthalene ring).

Examples of such compounds include compounds having a partial structure of formula (5-1) below, and polymers or oligomers having a repeating unit of formula (5-2) below.

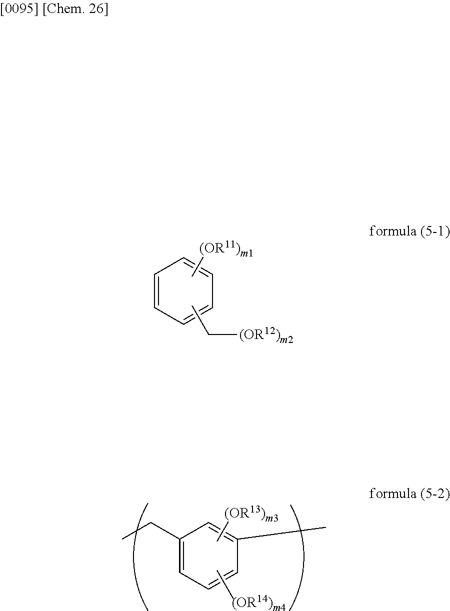

R¹¹, R¹², R^{—}and R¹⁴ are each a hydrogen atom or a C₁-C₁₀ alkyl group. m1, m2, m3 and m4 each indicate an integer of 0 to 3. Examples of the C₁-C₁₀ alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group and 2-ethyl-3-methyl-cyclopropyl group.

m1 satisfies 1≤m1≤6−m2, m2 satisfies 1≤m2≤5, m3 satisfies 1≤m3≤4−m2, and m4 satisfies 1≤m4≤3.

Examples of the compounds, the polymers and the oligomers having formula 5-1) or formula (5-2) are illustrated below.

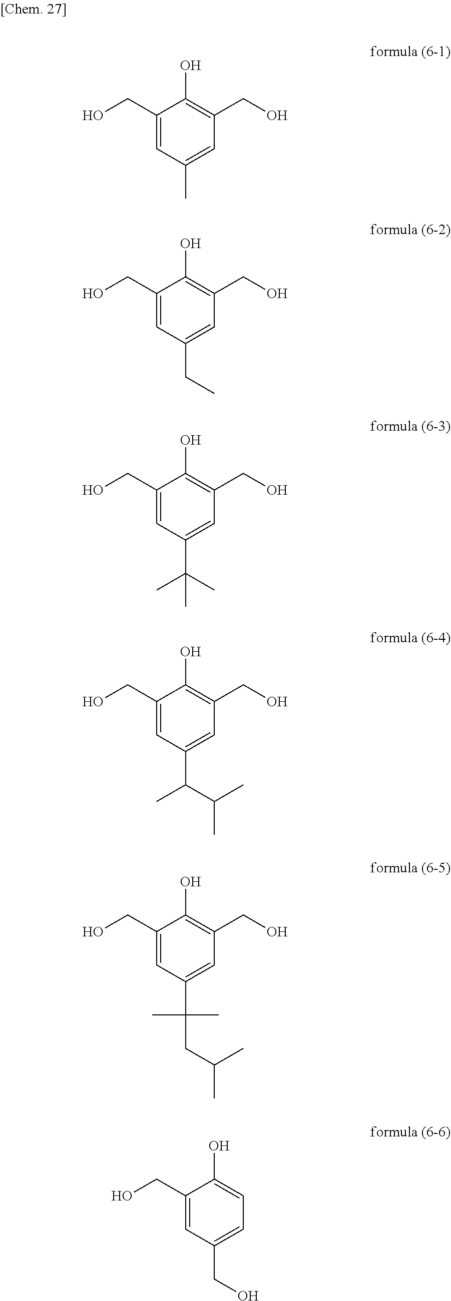

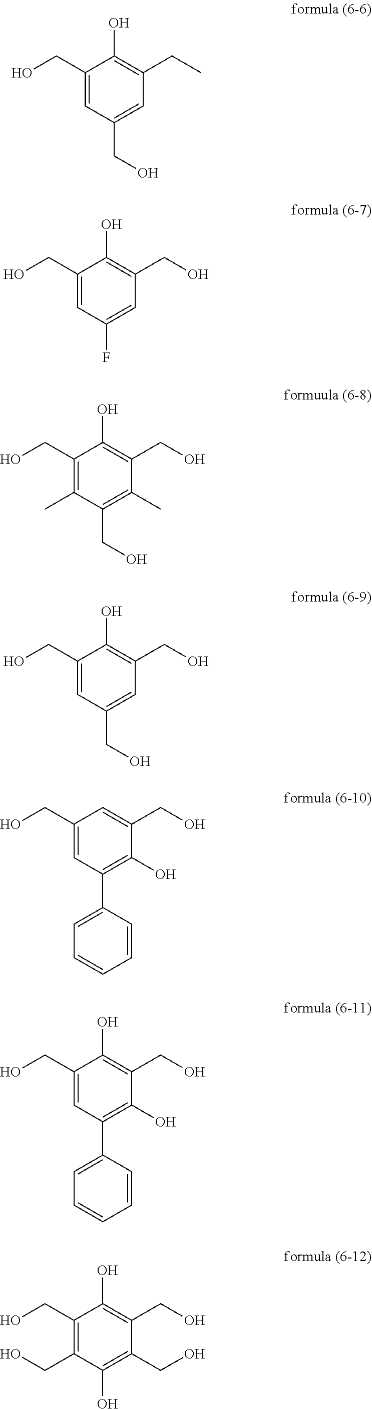

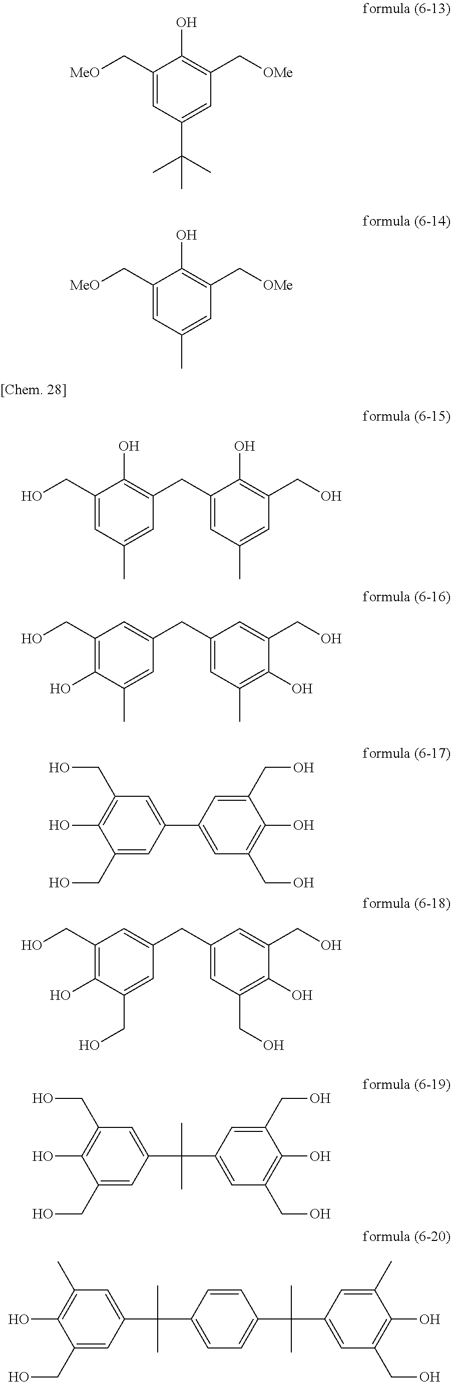

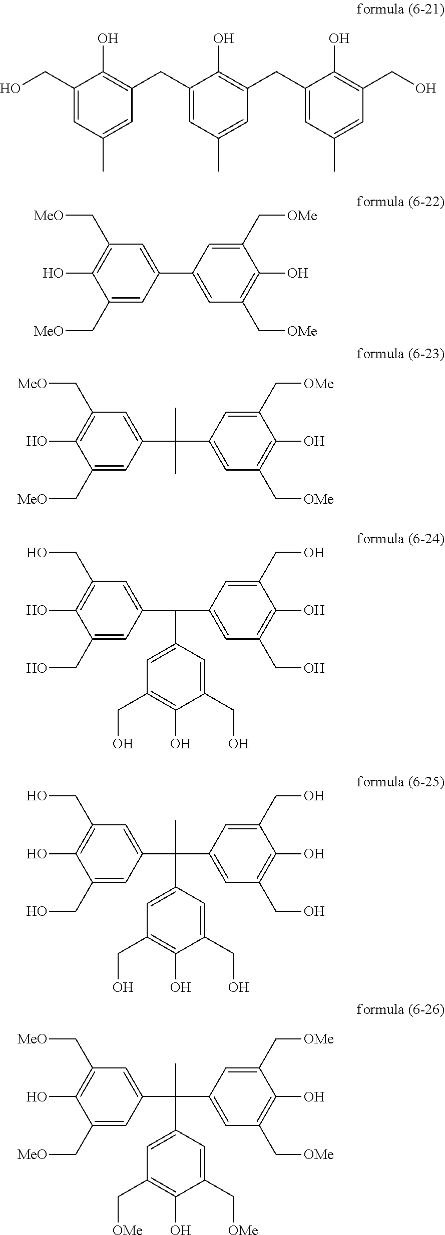

The compounds enumerated above may be obtained as products from ASAHI YUKIZAI CORPORATION and Honshu Chemical Industry Co, Ltd. Of the crosslinking agents illustrated above, for example, the compound of formula (6-22) is available under the trade name TMOM-BP from ASAHI YUKIZAI CORPORATION.

The amount of crosslinking agent added varies depending on factors such as the coating solvent that is used, the base substrate that is used, the required solution viscosity and the required film shape, but may be within the range of 0.001 to 80% by mass, preferably 0.01 to 50% by mass, and more preferably 0.1 to 40%, by mass of the total solid content in the resist underlayer film-forming composition. Although the crosslinking agents mentioned above may undergo crosslinking reaction by self-condensation, they can cause crosslinking reaction with the crosslinking substituent, if any, of the polymer of the present invention described above.

[Surfactant]

The resist underlayer film-forming composition of the present invention may include a surfactant as an optional component for enhancing the applicability to a semiconductor substrate. Examples of the surfactant include nonionic surfactants such as polyoxyethylene alkyl ethers including polyoxyethylene lauryl ether, poly oxyethylene stearyl ether, polyoxyethylene cetyl ether and polyoxyethylene oleyl ether, polyoxyethylene alkylaryl ethers including polyoxyethylene octylphenyl ether and polyoxyethylene nonylphenyl ether, polyoxyethylene/polyoxypropylene block copolymers, sorbitan fatty acid esters including sorbitan monolaurate, sorbitan monopalmitate, sorbitan monostearate, sorbitan monooleate, sorbitan trioleate and sorbitan tristearate, and polyoxyethylene sorbitan fatty acid esters including polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate; fluorosurfactants such as EFTOP [registered trademark] series EF301, EF303 and EF352 (manufactured by Mitsubishi Materials Electronic Chemicals Co., Ltd.), MEGAFACE [registered trademark] series F71, F173, R-30, R-30N, R-40 and R-40-LM (manufactured by DIC CORPORATION), Fluorad series FC430 and FC431 (manufactured by Sumitomo 3M Limited), AsahiGuard [registered trademark] AG710, and Surflon [registered trademark] series S-382, SC101, SC102, SC103, SC104, SC105 and SC106 (manufactured by AGC Inc.); and organosiloxane polymer KP341 (manufactured by Shin-Etsu Chemical Co., Ltd.). The surfactants may be used each alone or in combination of two or more. When the resist underlayer film-forming composition includes the surfactant, the content thereof is within the range of 0.0001 to 10% by mass, and preferably 0.01 to 5% by mass of the total solid content in the resist underlayer film-forming composition.

The solid content in the resist underlayer film-forming composition according to the present invention is usually within the range of 0.1 to 70% by mass, and preferably 0.1 to 60% by mass. The solid content is the proportion of all the components except the solvent in the resist underlayer film-forming composition. The proportion of the compounds or the reaction product according to the present application in the solid content is within the range of 1 to 100% by mass, 1 to 99.9% by mass, 50 to 99.9% by mass, 50 to 95% by mass, or 50 to 90%, by mass with increasing preference.

[Other Components]

Other components such as light absorbers, rheology modifiers and adhesion aids may be added to the resist underlayer film-forming composition of the present invention. Rheology modifiers are effective for enhancing the fluidity of the resist underlayer film-forming composition. Adhesion aids are effective for enhancing the adhesion between an underlayer film and a semiconductor substrate or a resist.

Some example light absorbers which may be suitably used are commercially available light absorbers described in “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; and C. I. Pigment Brown 2. The light absorber is usually added in a proportion of 10% by mass or less, and preferably 5% by mass or less relative to the total solid content in the resist underlayer film-forming composition.

The rheology modifier may be added mainly to enhance the fluidity of the resist underlayer film-forming composition and thereby, particularly in the baking step, to increase the uniformity in thickness of the resist underlayer film and to enhance the filling performance of the resist underlayer film-forming composition with respect to the inside of holes. Specific examples thereof include phthalic acid derivatives such as dimethyl phthalate, diethyl phthalate, diisobutyl phthalate, dihexyl phthalate and butyl isodecyl phthalate; adipic acid derivatives such as di-n-butyl adipate, diisobutyl adipate, diisooctyl adipate and octyl decyl adipate; maleic acid derivatives such as di-n-butyl maleate, diethyl maleate and dinonyl maleate; oleic acid derivatives such as methyl oleate, butyl oleate and tetrahydrofurfuryl oleate; and stearic acid derivatives such as n-butyl stearate and glyceryl stearate. The rheology modifier is usually added in a proportion of less than 30/% by mass relative to the total solid content in the resist underlayer film-forming composition.

The adhesion aid may be added mainly to enhance the adhesion between the resist underlayer film-forming composition and a substrate or resist and thereby to prevent the detachment of the resist particularly during development. Specific examples thereof include chlorosilanes such as trimethylchlorosilane, dimethylmethylolchlorosilane, methyldiphenylchlorosilane and chloromethyldimethylchlorosilane; alkoxysilanes such as trimethylmethoxysilane, dimethyldiethoxysilane, methyldimethoxysilane, dimethylmethylolethoxysilane, diphenyldimethoxysilane and phenyltriethoxysilane; silazanes such as hexamethyldisilazane, N,N′-bis(trimethylsilyl)urea, dimethyltrimethylsilylamine and trimethylsilylimidazole; silanes such as methyloltrichlorosilane, γ-chloropropyltrimethoxysilane, J-aminopropyltriethoxysilane and γ-glycidoxypropyltrimethoxysilane; heterocyclic compounds such as benzotriazole, benzimidazole, indazole, imidazole, 2-mercaptobenzimidazole, 2-mercaptobenzothiazole, 2-mercaptobenzoxazole, urazole, thiouracyl, mercaptoimidazole and mercaptopyrimidine; and urea or thiourea compounds such as 1,1-dimethylurea and 1,3-dimethylurea. The adhesion aid is usually added in a proportion of less than 5% by mass, and preferably less than 2% by mass relative to the total solid content in the resist underlayer film-forming composition.

[Resist underlayer film, method for producing pattern-bearing substrate, and method for manufacturing semiconductor device]

The following describes a resist underlayer film produced using the resist underlayer film-forming composition according to the present invention, and a method for producing a pattern-bearing substrate and a method for manufacturing a semiconductor device.

(Resist Underlayer Film)

A resist underlayer film according to the present invention may be produced by applying the resist underlayer film-forming composition described hereinabove onto a semiconductor substrate, and calcining the composition.

Examples of the semiconductor substrates to which the resist underlayer film-forming composition of the present invention is applied include silicon wafers, germanium wafers, and compound semiconductor wafers such as gallium arsenide, indium phosphide, gallium nitride, indium nitride and aluminum nitride.

The semiconductor substrate that is used may have an inorganic film on its surface. For example, such an inorganic film is formed by ALD (atomic layer deposition), CVD (chemical vapor deposition), reactive sputtering, ion plating, vacuum deposition or spin coating (spin on glass: SOG). Examples of the inorganic film include polysilicon films, silicon oxide films, silicon nitride films, BPSG (boor-phospho silicate glass) films, titanium nitride films, titanium oxynitride films, tungsten films, gallium nitride films and gallium arsenide films.

The resist underlayer film-forming composition of the present invention is applied onto such a semiconductor substrate with an appropriate applicator such as a spinner or a coater. Thereafter, the composition is baked with a heating device such as a hot plate to form a resist underlayer film. The baking conditions are appropriately selected from baking temperatures of 100° C. to 400° C. and amounts of baking time of 0.3 minutes to 60 minutes. Preferably, the baking temperature is 120° C. to 350° C. and the baking time is 0.5 minutes to 30 minutes. More preferably, the baking temperature is 150° C. to 300° C. and the baking time is 0.8 minutes to 10 minutes.

The thickness of the resist underlayer film formed is, for example, within the range of 0.001 μm (1 nm) to 10 μm, preferably 0.002 μm (2 nm) to 1 μm, and more preferably 0.005 μm (5 nm) to 0.5 μm (500 nm). If the baking temperature is lower than the above range, the composition is crosslinked insufficiently. If, on the other hand, the baking temperature is higher than the above range, the resist underlayer film may sometimes be decomposed by heat.

(Method for Producing Pattern-Bearing Substrate)

A pattern-bearing substrate is produced through the following steps. Usually, a pattern-bearing substrate is produced by forming a photoresist layer on the resist underlayer film. The photoresist may be formed on the resist underlayer film by application and calcination according to a method known per se, and is not particularly limited as long as the resist is sensitive to light used for photoexposure. Any of negative photoresists and positive photoresists may be used. Examples include positive photoresists composed of a novolak resin and 1,2-naphthoquinonediazide sulfonic acid ester; chemically amplified photoresists composed of a photoacid generator and a binder having a group that is decomposed by an acid to increase the alkali dissolution rate; chemically amplified photoresists composed of an alkali-soluble binder, a photoacid generator and a low-molecular compound that is decomposed by an acid to increase the alkali dissolution rate of the photoresist; and chemically amplified photoresists composed of a photoacid generator, a binder having a group that is decomposed by an acid to increase the alkali dissolution rate, and a low-molecular compound that is decomposed by an acid to increase the alkali dissolution rate of the photoresist. Specific examples include V146G, produce name, manufactured by JSR CORPORATION; APEX-E, produce name, manufactured by Shipley; PAR710, produce name, manufactured by Sumitomo Chemical Co., Ltd.; and AR2772 and SEPR430, produce names, manufactured by Shin-Etsu Chemical Co., Ltd. Examples further include fluorine-containing polymer photoresists such as those described in Proc. SPIE, Vol. 3999, 330-334 (2000), Proc. SPIE, Vol. 3999, 357-364 (2000) and Proc. SPIE, Vol. 3999, 365-374 (2000).

Exposure is performed using, for example, i-line radiation, KrF excimer laser beam, ArF excimer laser beam, EUV (extreme ultraviolet ray) or EB (electron beam) through a mask (a reticle) designed to form a predetermined pattern. An alkaline developer is used for the development, and the conditions are appropriately selected from development temperatures of 5° C. to 50° C. and amounts of development time of 10 seconds to 300 seconds. Examples of the alkaline developer include aqueous solutions of alkalis such as inorganic alkalis including sodium hydroxide, potassium hydroxide, sodium carbonate, sodium silicate, sodium metasilicate and aqueous ammonia, primary amines including ethylamine and n-propylamine, secondary amines including diethylamine and di-n-butylamine, tertiary amines including triethylamine and methyldiethylamine, alcohol amines including dimethylethanolamine and triethanolamine, quaternary ammonium salts including tetramethylammonium hydroxide, tetraethylammonium hydroxide and choline, and cyclic amines including pyrrole and piperidine. Appropriate amounts of an alcohol such as isopropyl alcohol and a surfactant such as nonionic surfactants may be added to the aqueous alkali solution described above. Of the developers mentioned above, quaternary ammonium salts are preferable, and tetramethylammonium hydroxide and choline are more preferable. Additional components such as surfactant may be added to the developer. An organic solvent such as butyl acetate may be used in place of the alkaline developer to develop portions of the photoresist that remain low in alkali dissolution rate. A substrate having a pattern of the resist may be produced through the steps described above.

Next, the resist underlayer film is dry-etched using as a mask the resist pattern formed. When the inorganic film described hereinabove is present on the surface of the semiconductor substrate that is used, the etching process exposes the surface of the inorganic film. When there is no inorganic film on the surface of the semiconductor substrate that is used, the etching process exposes the surface of the semiconductor substrate. The substrate is then processed by a method known per se (such as a dry etching process). A semiconductor device may be thus manufactured.

### EXAMPLES

The weight average molecular weight (Mw) of polymers described in Synthesis Examples below in the present specification is results measured by gel permeation chromatography (hereinafter, abbreviated as GPC). The measurement was performed using a GPC device manufactured by TOSOH CORPORATION under the following measurement conditions.

GPC columns: Shodex [registered trademark]-Asahipak [registered trademark](SHOWA DENKO K.K.)

Column temperature: 40° C.

Solvent: Tetrahydrofuran (THF)

Flow rate: 0.35 ml/min

Standard samples: Polystyrenes (TOSOH CORPORATION)

(Synthesis of ingredient monomers)

### Synthesis Example 1

38.70 g of tri(carboxymethyl) isocyanurate (TAICA) synthesized in accordance with the method described in U.S. Pat. No. 3,230,220, 300.00 g of N-methyl-2-pyrrolidone (manufactured by KANTO CHEMICAL CO., INC.), 70.91 g of allyl bromide (manufactured by Tokyo Chemical Industry Co., Ltd.) and 79.38 g of potassium carbonate (manufactured by KANTO CHEMICAL CO., INC.) were placed, and the temperature was raised to 80 to 90° C. The reaction was performed for 2 hours, and a constant amount of the reaction was confirmed. After the completion of the reaction, 580.50 g of toluene (manufactured by KANTO CHEMICAL CO., INC.) was added thereto, Filtration was performed, and the filtrate was washed with 580.50 g of water three times. The organic layer was concentrated to dryness, and 387.00 g of ethanol (manufactured by KANTO CHEMICAL CO., INC.) was added thereto. The resultant mixture was stirred at 20 to 30° C. for 30 minutes. After the completion of the stirring, the mixture was filtered and the crystal obtained was dried, Thus, 44.32 g of the target product (tri(allylacetato)isocyanuric acid: TAAICA) represented by formula (A1-1) was obtained in a yield of 85.2%.

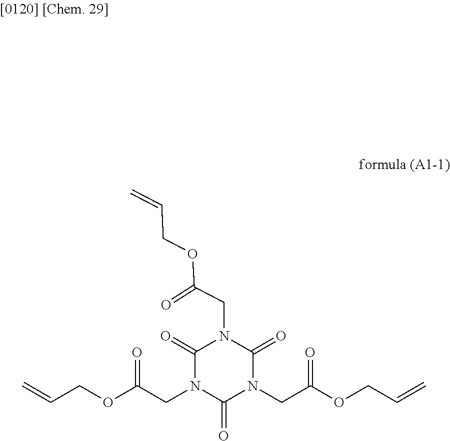 [SMILES: C=CCOC(=O)Cn1c(=O)n(CC(=O)OCC=C)c(=O)n(CC(=O)OCC=C)c1=O]

### Synthesis Example 2

44.32 g of TAAICA synthesized in Synthesis Example 1 and 443.20 g of chloroform (manufactured by KANTO CHEMICAL CO., INC.) were placed. Thereto was added 125.06 g of m-chloroperbenzoic acid (manufactured by Tokyo Chemical Industry Co., Ltd.). The reaction was performed for 47 hours. After the completion of the reaction, 88.64 g of chloroform (manufactured by KANTO CHEMICAL CO., INC.) was added thereto. Further, the mixture was washed with 886.40 g of 5% sodium hydrogen carbonate (manufactured by KANTO CHEMICAL CO., INC.), subsequently washed with 443.20 g of 10% sodium sulfite (manufactured by KANTO CHEMICAL CO., INC.) and 886.40 g of 5% sodium hydrogen carbonate (manufactured by KANTO CHEMICAL CO., INC.), and further washed twice with 443.20 g of water. After concentration was performed, the residue was purified by column purification. After the column purification, 41.31 g of the target product (tri(glycidylacetato)isocyanuric acid: TAGICA) represented by formula (A1-2) was obtained in a yield of 83.7%.

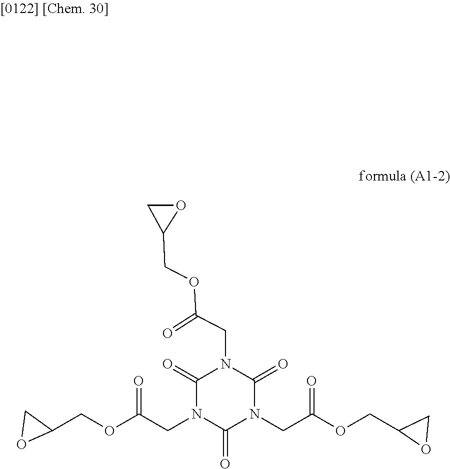 [SMILES: O=C(Cn1c(=O)n(CC(=O)OCC2CO2)c(=O)n(CC(=O)OCC2CO2)c1=O)OCC1CO1]

### Synthesis Example 3

In a reaction flask, 4205 g of propylene glycol monomethyl ether was added to 5.00 g of TAGICA obtained in Synthesis Example 2, 5.22 g of 2-mercapto-5-methylthio-1,3,4-thiadiazole and 0.41 g of ethyltriphenylphosphonium bromide. In a nitrogen atmosphere, the mixture was heated at 105° C. while stirring for 23 hours to give a reaction product corresponding to formula (A1-3). The weight average molecular weight Mw in terms of polystyrene measured by GPC was 1,000.

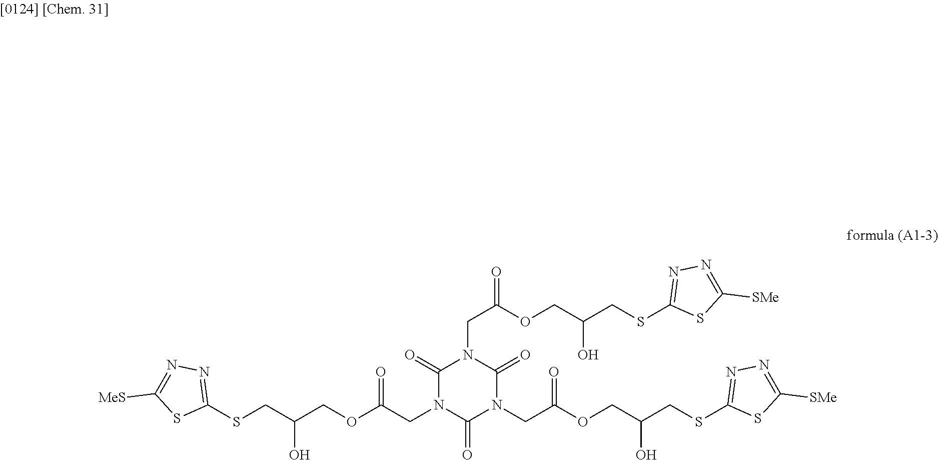 [SMILES: CSc1nnc(SCC(O)COC(=O)Cn2c(=O)n(CC(=O)OCC(O)CSc3nnc(SC)s3)c(=O)n(CC(=O)OCC(O)CSc3nnc(SC)s3)c2=O)s1]

### Synthesis Example 4

In a reaction flask, 36.91 g of propylene glycol monomethyl ether was added to 5.00 g of TAGICA obtained in Synthesis Example 2, 3.82 g of 2-mercapto-1,3,4-thiadiazole and 0.41 g of ethyltriphenylphosphonium bromide. In a nitrogen atmosphere, the mixture was heated at 105° C. while stirring for 4 hours to give a reaction product corresponding to formula (A1-4). The weight average molecular weight Mw in terms of polystyrene measured by GPC was 850.

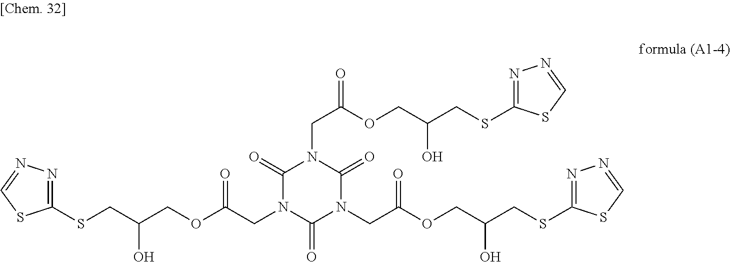 [SMILES: O=C(Cn1c(=O)n(CC(=O)OCC(O)CSc2nncs2)c(=O)n(CC(=O)OCC(O)CSc2nncs2)c1=O)OCC(O)CSc1nncs1]

### Synthesis Example 5

In a reaction flask, 38.42 g of propylene glycol monomethyl ether was added to 5.00 g of TAGICA obtained in Synthesis Example 2, 4.20 g of 2-mercapto-5-methyl-1,3,4-thiadiazole and 0.41 g of ethyltriphenylphosphonium bromide. In a nitrogen atmosphere, the mixture was heated at 105° C. while stirring for 22 hours to give a reaction product corresponding to formula (A1-5). The weight average molecular weight Mw in terms of polystyrene measured by GPC was 800.

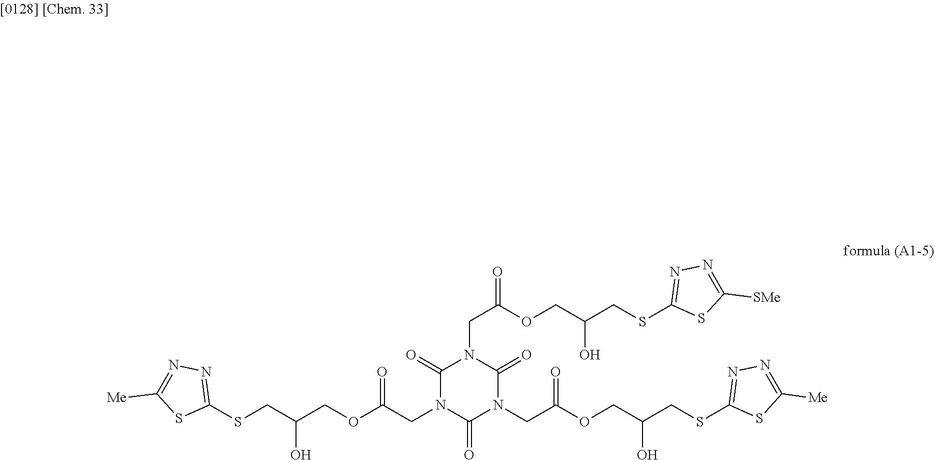 [SMILES: CSc1nnc(SCC(O)COC(=O)Cn2c(=O)n(CC(=O)OCC(O)CSc3nnc(C)s3)c(=O)n(CC(=O)OCC(O)CSc3nnc(C)s3)c2=O)s1]

### Synthesis Example 6

In a reaction flask, 36.37 g of propylene glycol monomethyl ether was added to 5.00 g of TAGICA obtained in Synthesis Example 2, 3.69 g of 5-mercapto-1-methyltetrazole and 0.41 g of ethyltriphenylphosphonium bromide. In a nitrogen atmosphere, the mixture was heated at 105° C. while stirring for 24 hours to give a reaction product corresponding to formula (A1-6). The weight average molecular weight Mw in terms of polystyrene measured by GPC was 800.

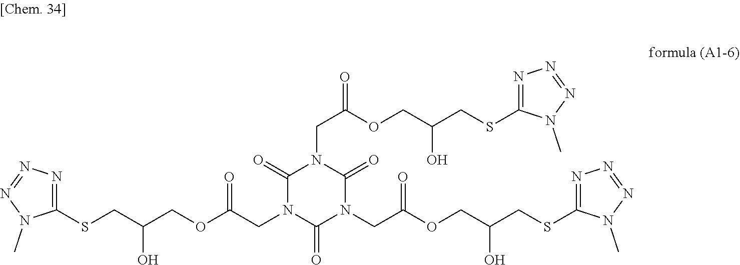 [SMILES: Cn1nnnc1SCC(O)COC(=O)Cn1c(=O)n(CC(=O)OCC(O)CSc2nnnn2C)c(=O)n(CC(=O)OCC(O)CSc2nnnn2C)c1=O]

### Synthesis Example 7

In a reaction flask, 37.89 g of propylene glycol monomethyl ether was added to 5.00 g of TAGICA obtained in Synthesis Example 2, 4.07 g of 1H-tetrazole-1-acetic acid and 0.41 g of ethyltriphenylphosphonium bromide. In a nitrogen atmosphere, the mixture was heated at 105° C. while stirring for 24 hours to give a reaction product corresponding to formula (A1-7). The weight average molecular weight Mw in terms of polystyrene measured by GPC was 850.

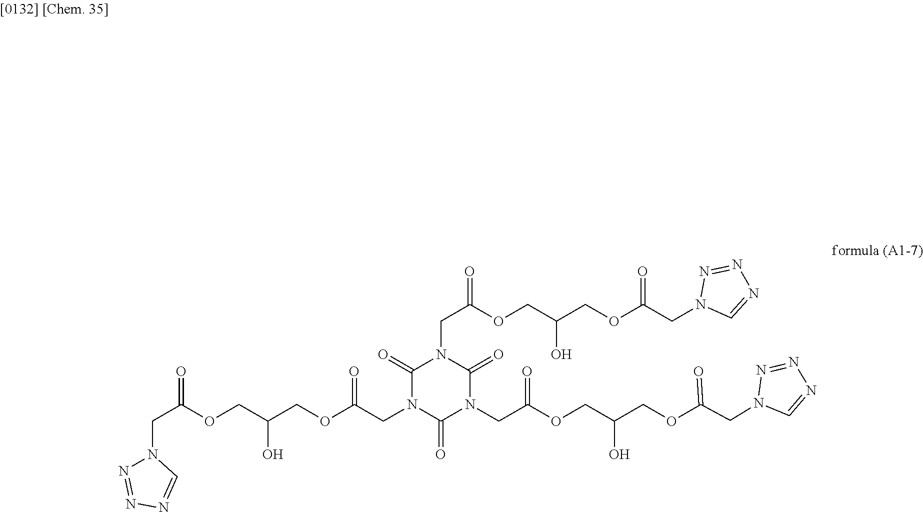 [SMILES: O=C(Cn1cnnn1)OCC(O)COC(=O)Cn1c(=O)n(CC(=O)OCC(O)COC(=O)Cn2cnnn2)c(=O)n(CC(=O)OCC(O)COC(=O)Cn2cnnn2)c1=O]

### Synthesis Example 8

10.00 g of methylisocyanuric acid (Me-ICA) synthesized in accordance with the method described in patent gazette (WO 2017/208910), 14.49 g of potassium carbonate (manufactured by KANTO CHEMICAL CO., INC.), 20.48 g of allyl chloroacetate (manufactured by Aldrich) and 40.00 g of N,N-dimethylformamide (manufactured by KANTO CHEMICAL CO., INC.) were placed and the mixture was stirred at 60° C. for 25 hours. 100.00 g of toluene (manufactured by KANTO CHEMICAL CO., INC.) was added thereto, and filtered. 100.00 g of water was added to the filtrate, and separated at 50° C. 100.00 g of water was further added to the obtained organic layer, and separated at 50° C. Concentrating the thus obtained organic layer gave 20.51 g of the target product (methyldi(allylacetato)isocyanuric acid: Me-DAAICA) represented by formula (B1-1) in a yield of 86.5%.

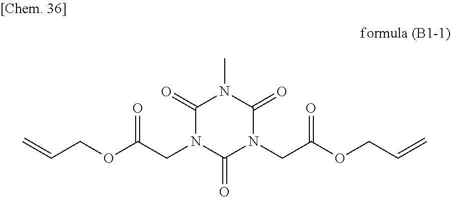 [SMILES: C=CCOC(=O)Cn1c(=O)n(C)c(=O)n(CC(=O)OCC=C)c1=O]

### Synthesis Example 9

20.51 g of Me-DAAICA obtained in Synthesis Example 8 and 153.83 g of chloroform (manufactured by KANTO CHEMICAL CO., INC.) were placed. Further, 38.52 g of n-chloroperbenzoic acid (manufactured by Tokyo Chemical Industry Co., Ltd.) was added thereto. The reaction was performed for 71 hours, and a constant amount of the reaction was confirmed. After the completion of the reaction, 205.10 g of chloroform (manufactured by KANTO CHEMICAL CO., INC.) and 410.20 g of 5 wt % sodium hydrogen carbonate (manufactured by KANTO CHEMICAL CO., INC) were added thereto. The liquid mixture was separated, and 205.10 g of 10 wt % sodium sulfite (manufactured by KANTO CHEMICAL CO., INC.) was added to the obtained organic layer. The liquid mixture was separated again, and 410.20 g of 5 wt % sodium hydrogen carbonate (manufactured by KANTO CHEMICAL CO., INC.) was added to the obtained organic layer, and separated. The organic layer thus obtained was washed twice with 205.10 g of water. Concentrating the organic layer to dryness followed by column purification gave 10.46 g of the target product (methyldi(glycidylacetato)isocyanuric acid: Me-DAGICA) represented by formula (B1-2) in a yield of 46.6%.

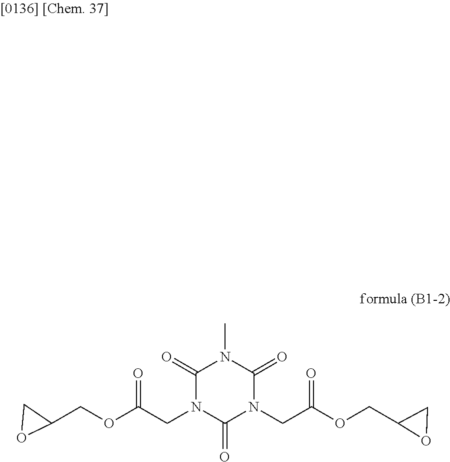 [SMILES: Cn1c(=O)n(CC(=O)OCC2CO2)c(=O)n(CC(=O)OCC2CO2)c1=O]

### Synthesis Example 10

In a reaction flask, 38.91 g of propylene glycol monomethyl ether was added to 5.00 g of Me-DAGICA obtained in Synthesis Example 9, 4.60 g of 2-mercapto-5-methylthio-1,3,4-thiadiazole and 0.13 g of ethyltriphenylphosphonium bromide. In a nitrogen atmosphere, the mixture was heated at 105° C. while stirring for 23 hours to give a reaction product corresponding to formula (B1-3). The weight average molecular weight Mw in terms of polystyrene measured by GPC was 600.

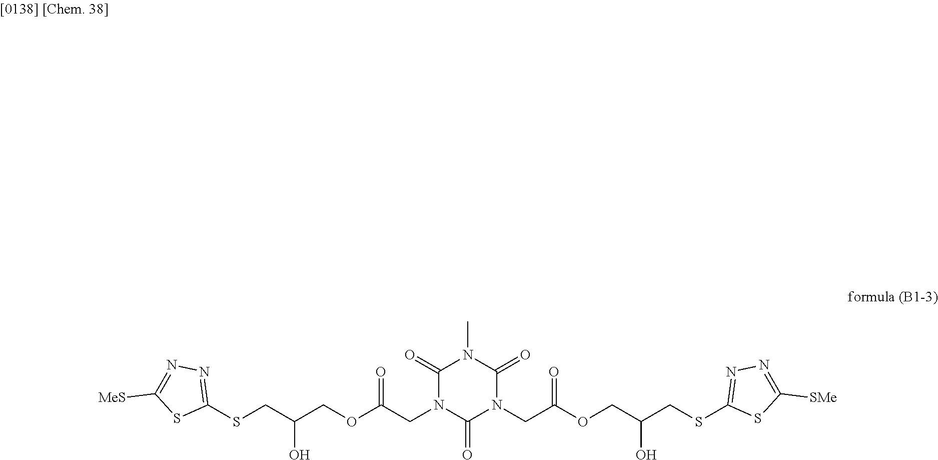 [SMILES: CSc1nnc(SCC(O)COC(=O)Cn2c(=O)n(C)c(=O)n(CC(=O)OCC(O)CSc3nnc(SC)s3)c2=O)s1]

### Synthesis Example 11

In a reaction flask, 38.02 g of propylene glycol monomethyl ether was added to 5.00 g of TAGICA obtained in Synthesis Example 2, 4.10 g of thiazole-4-carboxylic acid and 0.41 g of ethyltriphenylphosphonium bromide. In a nitrogen atmosphere, the mixture was heated at 105° C. while stirring for 24 hours to give a reaction product corresponding to formula (A1-8). The weight average molecular weight Mw in terms of polystyrene measured by GPC was 1,200.

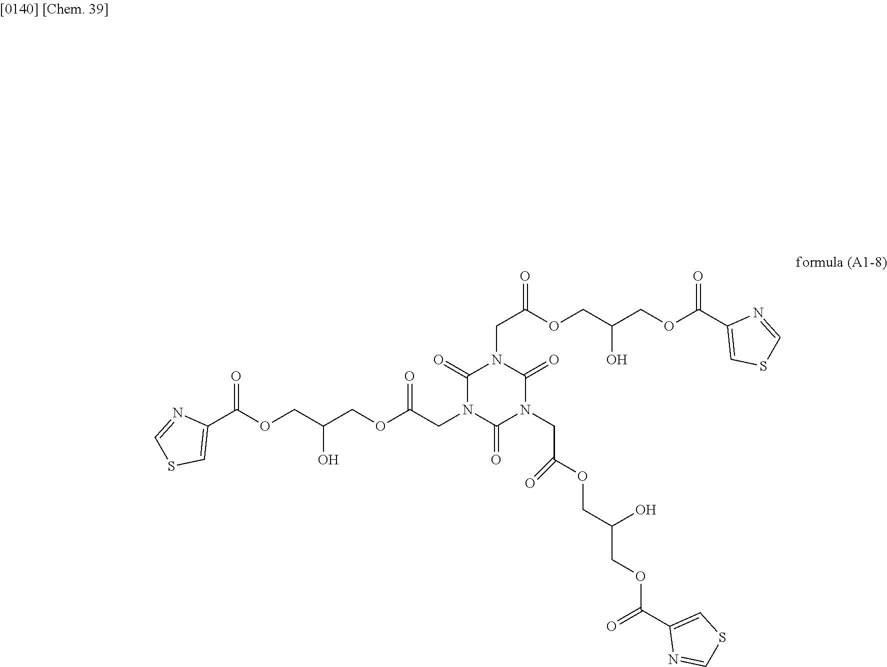 [SMILES: O=C(Cn1c(=O)n(CC(=O)OCC(O)COC(=O)c2cscn2)c(=O)n(CC(=O)OCC(O)COC(=O)c2cscn2)c1=O)OCC(O)COC(=O)c1cscn1]

### Synthesis Example 12

In a reaction flask. 36.50 g of propylene glycol monomethyl ether was added to 5.00 g of TAGICA obtained in Synthesis Example 2, 3.72 g of 2-mercaptothiazole and 0.41 g of ethyltriphenylphosphonium bromide. In a nitrogen atmosphere, the mixture was heated at 105° C. while stirring for 24 hours to give a reaction product corresponding to formula (A1-9). The weight average molecular weight Mw in terms of polystyrene measured by GPC was 760.

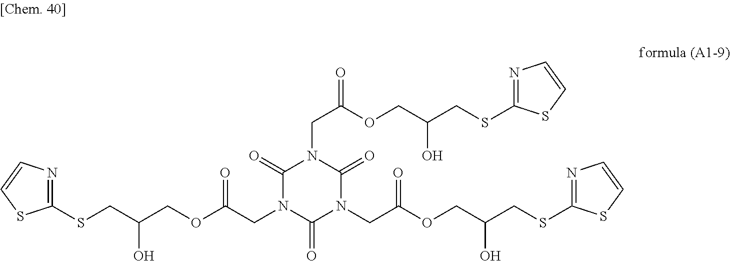 [SMILES: O=C(Cn1c(=O)n(CC(=O)OCC(O)CSc2nccs2)c(=O)n(CC(=O)OCC(O)CSc2nccs2)c1=O)OCC(O)CSc1nccs1]

(Preparation of Composition)

### Example 1

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 3 containing 0.23 g of the reaction product. Thereafter, filtering the solution through a polyethylene microfilter having a pore size of 0.02 μm gave a resist underlayer film-forming composition.

### Example 2

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 4 containing 0.23 g of the reaction product. Thereafter, filtering the solution through a polyethylene microfilter having a pore size of 0.02 μm gave a resist underlayer film-forming composition.

### Example 3

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 5 containing 0.23 g of the reaction product. Thereafter, filtering the solution through a polyethylene microfilter having a pore size of 0.02 in gave a resist underlayer film-forming composition.

### Example 4

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 6 containing 0.23 g of the reaction product. Thereafter, filtering the solution through a polyethylene microfilter having a pore size of 0.02 μm gave a resist underlayer film-forming composition.

### Example 5

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 7 containing 0.23 g of the reaction product. Thereafter, filtering the solution through a polyethylene microfilter having a pore size of 0.02 μm gave a resist underlayer film-forming composition.

### Example 6

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 10 containing 0.23 g of the reaction product. Thereafter, filtering the solution through a polyethylene microfilter having a pore size of 0.02 μm gave a resist underlayer film-forming composition.

### Example 7

A solution was obtained by adding 29.70 g of propylene glycol monomethyl ether, 0.06 n of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 11 containing 0.23 g of the reaction product. Thereafter, filtering the solution through a polyethylene microfilter having a pore size of 0.02 μm gave a resist underlayer film-forming composition.

### Example 8

A solution was obtained by adding 29.70 g of propylene glycol monomethyl ether, 0.06 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.001 g of a surfactant (produce name: R-40, DIC CORPORATION) to 1.23 g of the solution from Synthesis Example 12 containing 0.23 g of the reaction product. Thereafter, filtering the solution through a polyethylene microfilter having a pore size of 0.02 μm gave a resist underlayer film-forming composition.

### Comparative Example 1

To 3.58 g of a solution obtained by the method described in Synthesis Example 1 of WO 2009/096340 and having a content of the reaction product of 0.72 g were added 88.43 g of propylene glycol monomethyl ether, 9.90 g of propylene glycol monomethyl ether acetate, 0.18 g of tetramethoxymethylglycoluril (produce name: POWDERLINK [registered trademark] 1174, Cytec Industries Incorporated, Japan), 0.01 g of phenolsulfonic acid (Tokyo Chemical Industry Co., Ltd.) and 0.01 g of a surfactant (produce name: R-40, DIC CORPORATION), to obtain a solution. Thereafter, filtering the solution through a polyethylene microfilter having a pore size of 0.02 μm gave a resist underlayer film-forming composition.

(Measurement of Dry Etching Rate)

Each of the resist underlayer film-forming compositions prepared in Examples 1 to 8 and Comparative Example 1 was applied onto a silicon wafer using a spinner, and the coating was baked on a hot plate at 205° C. for 1 minute to form a resist underlayer film having a film thickness of 100 nm. The resist underlayer film was etched with CF₄ as a dry etching gas using a dry etching device (RIE-10NR) manufactured by Samco Inc. to measure the dry etching rate (the decrease in film thickness per unit time). Table 1 shows the etching selectivity of each of the underlayer films relative to the etching selectivity of the resist underlayer film obtained in Comparative Example 1 taken as 1.00,

TABLE 1
Table 1

| Example | Etching selectivity (CF₄) |
|---|---|
| Example 1 | 1.51 |
| Example 2 | 1.44 |
| Example 3 | 1.33 |
| Example 4 | 1.42 |
| Example 5 | 1.36 |
| Example 6 | 1.55 |
| Example 7 | 1.15 |
| Example 8 | 1.14 |
| Comparative Example 1 | 1.00 |

The results show that Examples 1 to 8 attained sufficiently higher etching selectivity than Comparative Example 1. That is, the resist underlayer film-forming compositions obtained by the present invention enable reduction of period of time for dry-etching the resist underlayer films, and thereby permit suppressing undesired thickness loss of the resist film during the removal of the resist underlayer film by dry etching. Further, such a resist underlayer film is particularly useful, because the shortening of dry etching time makes it possible to protect a substrate lying under the resist underlayer film from an undesired etching damage.

(Evaluation of Optical Parameters)

Each of the resist underlayer film-forming compositions prepared in Examples 1 to 8 and Comparative Example 1 described in the present specification was applied (spin coated) onto a silicon wafer using a spin coater. By heating the coated silicon wafer on a hot plate at 205° C. for 1 minute, a resist underlayer film-forming composition (film thickness: 30 nm) was formed. The resist underlayer film-forming composition was analyzed with a spectroscopic ellipsometer (produce name: VUV-VASE VU-302, manufactured by J. A. Woollam) to measure the n value (refractive index) and the k value (attenuation coefficient or absorption coefficient) at a wavelength of 193 nm.

The results of the measurement of optical parameters are shown in Table 4.

TABLE 2
Table 2

| Example | n/k @193 nm |
|---|---|
| Example 1 | 1.93/0.26 |
| Example 2 | 1.93/0.24 |
| Example 3 | 1.92/0.21 |
| Example 4 | 1.87/0.21 |
| Example 5 | 1.85/0.17 |
| Example 6 | 1.94/0.28 |
| Example 7 | 1.76/0.26 |
| Example 8 | 1.90/0.23 |
| Comparative Example 1 | 1.94/0.28 |

### INDUSTRIAL APPLICABILITY

The resist underlayer film-forming composition according to the present invention can form a resist underlayer film having a particularly high dry etching rate.

1. A resist underlayer film-forming composition comprising a solvent and a reaction product formed between an epoxy group-containing compound and a heterocyclic compound having one site reactive with an epoxy group.

2. The resist underlayer film-forming composition according to claim 1, wherein the heterocyclic compound includes a heterocyclic ring selected from furan, pyrrol, pyran, imidazole, pyrazole, oxazole, thiophene, thiazole, thiadiazole, imidazolidine, thiazolidine, imidazoline, dioxane, morpholine, diazine, thiazine, triazole, tetrazole, dioxolane, pyridazine, pyrimidine, pyrazine, piperidine, piperazine, indole, purine, quinoline, isoquinoline, quinuclidine, chromene, thianthrene, phenothiazine, phenoxazine, xanthene, acridine, phenazine and carbazole.

3. The resist underlayer film-forming composition according to claim 1, wherein the site reactive with an epoxy group is selected from a hydroxy group, a thiol group, an amino group, an imide group and a carboxyl group.

4. The resist underlayer film-forming composition according to claim 1, wherein the epoxy group-containing compound is a compound represented by the following formula (1): 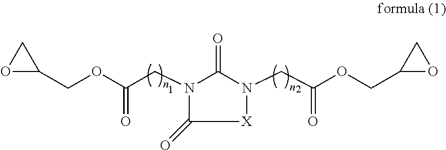
wherein X is a divalent organic group represented by formula (2), formula (3) or formula (4) below, and n₁ and n₂ are each independently an integer of 1 to 10, 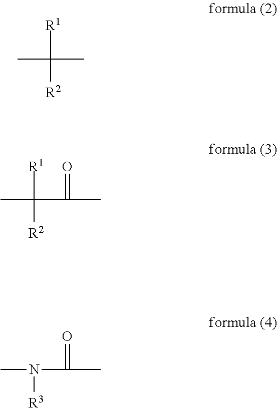
wherein
R¹ and R² each independently denote a hydrogen atom, a C₁-C₁₀ alkyl group optionally interrupted with an oxygen atom or a sulfur atom, a C₂-C₁₀ alkenyl group optionally interrupted with an oxygen atom or a sulfur atom, a C₂-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group and C₁-C₆ alkylthio groups; and
R³ denotes a hydrogen atom, a C₁-C₁₀ alkyl group optionally interrupted with an oxygen atom or a sulfur atom, a C₃-C₁₀ alkenyl group optionally interrupted with an oxygen atom or a sulfur atom, a C₃-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group, C₁-C₆ alkylthio groups and organic groups represented by the following formula (5): 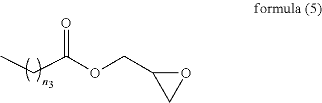
wherein n3 indicates an integer of 1 to 10.

5. The resist underlayer film-forming composition according to claim 1, further comprising at least one component selected from the group consisting of crosslinking agent, crosslinking catalyst and surfactant.

6. A resist underlayer film comprising a calcined product of a coating film comprising the resist underlayer film-forming composition according to claim 1.

7. A method for producing a pattern-bearing substrate, comprising the steps of:
applying the resist underlayer film-forming composition according to claim 1 onto a semiconductor substrate and baking the resist underlayer film-forming composition to form a resist underlayer film,
applying a resist onto the resist underlayer film and baking the resist to form a resist film,
exposing the semiconductor substrate coated with the resist underlayer film and the resist, and
developing the exposed resist film to perform patterning.

8. A method for manufacturing a semiconductor device, comprising the steps of:
forming, on a semiconductor substrate, a resist underlayer film from the resist underlayer film-forming composition according to claim 1,
forming a resist film on the resist underlayer film,
applying a light or electron beam to the resist film followed by development to form a resist pattern,
etching the resist underlayer film through the resist pattern to form a patterned resist underlayer film, and
processing the semiconductor substrate through the patterned resist underlayer film.

9. A reaction product of a compound represented by formula (1) below and a heterocyclic compound having one site reactive with an epoxy group, 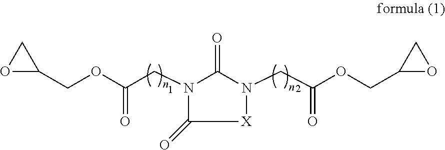
wherein X is a divalent organic group represented by formula (2), formula (3) or formula (4) below, and n₁ and n₂ are each independently an integer of 1 to 10, 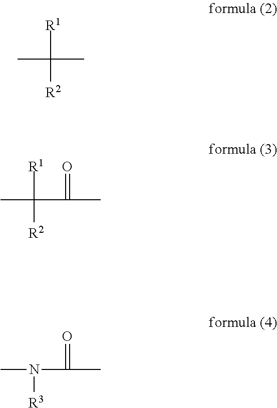
wherein
R¹ and R² each independently denote a hydrogen atom, a C₁-C₁₀ alkyl group optionally interrupted with an oxygen atom or a sulfur atom, a C₂-C₁₀ alkenyl group optionally interrupted with an oxygen atom or a sulfur atom, a C₂-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group and C₁-C₆ alkylthio groups; and
R³ denotes a hydrogen atom, a C₁-C₁₀ alkyl group optionally interrupted with an oxygen atom or a sulfur atom, a C₃-C₁₀ alkenyl group optionally interrupted with an oxygen atom or a sulfur atom, a C₃-C₁₀ alkynyl group optionally interrupted with an oxygen atom or a sulfur atom, a benzyl group or a phenyl group, and the phenyl group is optionally substituted with at least one monovalent functional group selected from the group consisting of C₁-C₆ alkyl groups, halogen atoms, C₁-C₁₀ alkoxy groups, nitro group, cyano group, C₁-C₆ alkylthio groups and organic groups represented by the following formula (5): 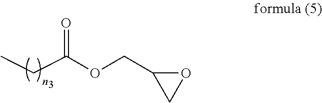
wherein n3 indicates an integer of 1 to 10.
